(19) United States
(12) Patent Application Publication
(10) Pub. No.: US 2026/0182159 A1
(43) Pub. Date: Jun. 25, 2026

(54) DISPLAY DEVICE, ELECTRONIC DEVICE, AND METHOD OF MANUFACTURING THE DISPLAY DEVICE

(71) Applicant: SAMSUNG DISPLAY CO., LTD., YONGIN-SI (KR)

(72) Inventors: Sam Tae JEONG, Yongin-si (KR); Su Kyoung YANG, Yongin-si (KR)

(21) Appl. No.: 19/295,863

(22) Filed: Aug. 11, 2025

(30) Foreign Application Priority Data
Dec. 23, 2024 (KR) 10-2024-0194135

(51) Int. Cl. H10K 59/123; H10K 59/12; H10K 59/124

(52) U.S. Cl. CPC H10K 59/123; H10K 59/1201; H10K 59/124

(57) ABSTRACT

A display device includes a substrate, a lower pattern, a lower insulating layer, an active layer, an upper insulating layer and an upper pattern consecutively disposed. The active layer has a portion including an end of the active layer overlapping the lower pattern. A contact hole penetrates the lower and upper insulating layers exposing a portion of the lower pattern and the end of the active layer. The upper pattern is electrically connected to the lower pattern and active layer through the contact hole. The contact hole includes a bottom portion exposing the portion of the lower pattern, a first sidewall portion exposing the end of the active layer and including an undercut under the active layer and a second sidewall portion. The upper pattern contacts the end of the active layer at the first sidewall portion, is broken under the active layer and continuous at the second sidewall portion.

This application claims priority under 35 U.S.C. § 119 to Korean Patent Application No. 10-2024-0194135, filed on Dec. 23, 2024 in the Korean Intellectual Property Office, the disclosure of which is incorporated by reference in its entirety herein.

### 1. TECHNICAL FIELD

Embodiments of the present disclosure relate to a display device, an electronic device, and a method of manufacturing the display device.

### 2. DISCUSSION OF RELATED ART

As the information society advances, consumer demand for display devices for displaying images in a variety of electronic devices has increased. Accordingly, various types of display devices including light emitting display devices are being developed. Display devices may be provided alone or may be included in electronic devices that can display images and used as display screens of the electronic devices.

### SUMMARY

Aspects of the present disclosure provide a display device, an electronic device and a method of manufacturing the display device which can prevent a contact failure that may occur in a contact hole and increase reliability.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an embodiment of the present disclosure, a display device includes a substrate. A lower pattern is disposed on the substrate. A lower insulating layer is disposed on the lower pattern. An active layer is disposed on the lower insulating layer and has at least a portion that includes an end of the active layer overlapping the lower pattern. An upper insulating layer is disposed on the active layer. A contact hole penetrates the lower insulating layer and the upper insulating layer to expose a portion of the lower pattern and the end of the active layer. An upper pattern is disposed on the upper insulating layer and the contact hole and is electrically connected to the lower pattern and the active layer through the contact hole. The contact hole comprises a bottom portion exposing the portion of the lower pattern, a first sidewall portion exposing the end of the active layer and comprising an undercut positioned under the active layer and a second sidewall portion facing the first sidewall portion. The upper pattern directly contacts the end of the active layer at the first sidewall portion. The upper pattern is broken under the active layer. The upper pattern is continuous along the second sidewall portion.

In an embodiment, the lower insulating layer and the upper insulating layer may include a plurality of insulating layers covered with the upper pattern at the first sidewall portion and the second sidewall portion and including different materials from each other, the first sidewall portion may include a step portion formed between the plurality of insulating layers, and the second sidewall portion may not include a step portion formed between the plurality of insulating layers or may include a step portion having a shorter length than the step portion formed between the plurality of insulating layers at the first sidewall portion.

In an embodiment, the first sidewall portion may include a step structure including the undercut, and the second sidewall portion may have a substantially smooth shape.

In an embodiment, the first sidewall portion may include a step structure including the undercut, and the second sidewall portion may include a step structure including an second undercut having a shorter length than the undercut of the first sidewall portion.

In an embodiment, a maximum length of the undercut formed at the second sidewall portion may be less than or equal to about 50% of a maximum length of the undercut of the first sidewall portion.

In an embodiment, the active layer may be disposed only at the first sidewall portion among the first sidewall portion and the second sidewall portion, and the first sidewall portion and the second sidewall portion may have a same stacked structure except for an inclusion of the active layer in the first sidewall portion.

In an embodiment, the upper pattern may extend continuously from a top of the contact hole onto the bottom portion of the contact hole via the second sidewall portion of the contact hole.

In an embodiment, the lower insulating layer and the upper insulating layer may include a silicon oxide layer and a silicon nitride layer.

In an embodiment, the silicon oxide layer may be opened wider than the silicon nitride layer in at least a portion of the contact hole including the first sidewall portion.

In an embodiment, the active layer may protrude more than the lower insulating layer and the upper insulating layer toward a center of the contact hole at the first sidewall portion.

In an embodiment, the active layer may include a lower surface exposed by the undercut at the first sidewall portion, and the upper pattern may not contact the lower surface of the active layer.

In an embodiment, a length of the undercut may be in a range of about 10 nm to about 100 nm.

In an embodiment, the upper pattern may include a main conductive layer and a barrier layer under the main conductive layer.

In an embodiment, the barrier layer may directly contact the end of the active layer, and the main conductive layer may not contact the active layer and may be electrically connected to the active layer through the barrier layer.

According to an embodiment of the present disclosure, there is provided a method of manufacturing a display device, the method including, sequentially forming a lower pattern, a lower insulating layer, an active layer, and an upper insulating layer on a substrate, forming a contact hole exposing a portion of the lower pattern and an end of the active layer by etching the lower insulating layer and the upper insulating layer, forming a mask on an entirety of a second sidewall portion facing a first sidewall portion where the active layer is exposed among sidewall portions of the contact hole, forming an undercut under the active layer by performing buffered oxide etching in a state where the first sidewall portion is exposed by the mask, and forming an upper pattern that is electrically connected to the lower pattern and the active layer through the contact hole, on the upper insulating layer and the contact hole.

In an embodiment, the forming of the mask may include depositing a sputtering material only on a portion of the contact hole including the entirety of the second sidewall portion by using an oblique sputtering method.

In an embodiment, the performing of the buffered oxide etching may include etching a side surface of each of the lower insulating layer and the upper insulating layer exposed by the mask at the first sidewall portion by using a buffered oxide etchant, and the mask may include a material having a lower etching rate for the buffered oxide etchant than the lower insulating layer and the upper insulating layer.

In an embodiment, the active layer may include a material having a lower etching rate for the buffered oxide etchant than the mask, and the lower insulating layer and the upper insulating layer may include a plurality of insulating layers comprising materials having different etching rates for the buffered oxide etchant from each other, the plurality of insulating layers may form a step portion at least at the first sidewall portion.

In an embodiment, the buffered oxide etching may be performed until the mask is etched to expose the lower insulating layer and the upper insulating layer at the second sidewall portion or the buffered oxide etching may be performed until the mask is etched and the lower insulating layer and the upper insulating layer exposed at the second sidewall portion is etched.

According to an embodiment of the present disclosure, an electronic device includes a display panel comprising a substrate and a circuit layer on the substrate. A housing accommodates the display panel. The circuit layer includes a lower pattern disposed on the substrate. A lower insulating layer is disposed on the lower pattern. An active layer is disposed on the lower insulating layer and has at least a portion that includes an end of the active layer overlapping the lower pattern. An upper insulating layer is disposed on the active layer. A contact hole penetrates the lower insulating layer and the upper insulating layer to expose a portion of the lower pattern and the end of the active layer. An upper pattern is disposed on the upper insulating layer and the contact hole and is electrically connected to the lower pattern and the active layer through the contact hole. The contact hole comprises a bottom portion exposing the portion of the lower pattern, a first sidewall portion exposing the end of the active layer and comprising an undercut positioned under the active layer and a second sidewall portion facing the first sidewall portion. The upper pattern directly contacts the end of the active layer at the first sidewall portion. The upper pattern is broken under the active layer and the upper pattern is continuous along the second sidewall portion.

According to embodiments, an active layer, a lower pattern under the active layer, and an upper pattern on the active layer may be connected by a single contact hole penetrating a plurality of insulating layers. Accordingly, a high-resolution display device or a high-resolution electronic device can be easily manufactured.

In addition, according to embodiments, the contact hole may have a differentiated sidewall structure for each of a connection path between the upper pattern and the lower pattern and a connection path between the upper pattern and the active layer. For example, the contact hole may include an undercut under the active layer at a first sidewall portion where the active layer is exposed, and the upper pattern may be broken or discontinuous under the active layer. In addition, the contact hole may have a smooth shape at a second sidewall portion facing the first sidewall portion compared to the first sidewall portion, and the upper pattern may be stably connected to the lower pattern via the second sidewall portion. Accordingly, the diffusion of a material of the upper pattern into the active layer can be prevented or reduced, a contact failure that may occur in the contact hole can be prevented, and the reliability of a display device or an electronic device can be increased.

However, effects according to the embodiments of the present disclosure are not limited to those described above and various other effects are incorporated herein.

### BRIEF DESCRIPTION OF THE DRAWINGS

These and/or other aspects will become apparent and more readily appreciated from the following description of non-limiting embodiments, taken in conjunction with the accompanying drawings in which:

FIG. 1 is a perspective view of a display device according to an embodiment of the present disclosure;

FIG. 2 is an equivalent circuit diagram of a pixel according to an embodiment of the present disclosure;

FIG. 3 is an equivalent circuit diagram of a pixel according to an embodiment of the present disclosure;

FIG. 4 is a cross-sectional view of the display device according to the embodiment of the present disclosure;

FIG. 5 is a cross-sectional view illustrating a contact hole according to an embodiment and a lower pattern, an active layer and an upper pattern connected through the contact hole according to the embodiment of the present disclosure;

FIG. 6 is a cross-sectional view illustrating a contact hole according to an embodiment and a lower pattern, an active layer and an upper pattern connected through the contact hole according to the embodiment of the present disclosure;

FIGS. 7 through 11 are cross-sectional views illustrating a method of manufacturing a display device according to embodiments of the present disclosure;

FIGS. 12 and 13 are cross-sectional views illustrating a method of manufacturing a display device according to embodiments of the present disclosure;

FIG. 14 is a perspective view of a head-mounted display device according to an embodiment of the present disclosure;

FIG. 15 is an exploded perspective view of an example of the head-mounted display device of FIG. 14 according to an embodiment of the present disclosure; and

FIG. 16 is a perspective view of a head-mounted display device according to an embodiment of the present disclosure.

FIG. 17 is a block diagram of an electronic device according to an embodiment of the present disclosure.

### DETAILED DESCRIPTION OF EMBODIMENTS

The present disclosure will now be described more fully hereinafter with reference to the accompanying drawings, in which non-limiting embodiments of the present disclosure are shown. The present disclosure may, however, be embodied in different forms and should not be construed as limited to the described embodiments set forth herein.

It will also be understood that when an element or a layer is referred to as being “on” another element or layer, it can be directly on the other element or layer, or intervening layers may also be present. When an element or a layer is referred to as being “directly on” another element or layer, no intervening layers may be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Features of each of various embodiments of the present disclosure may be partially or entirely combined with each other and may technically variously interwork with each other, and respective embodiments may be implemented independently of each other or may be implemented together in association with each other.

Specific non-limiting embodiments will be described below with reference to the attached drawings.

The present disclosure concerns a display device in which three or more patterns located in different layers from each other may be electrically connected to each other in a stable manner by one contact hole. The display device may have an upper pattern disposed in a contact hole. The contact hole exposes a portion of an intermediate pattern and a lower pattern to electrically connect the lower, intermediate and upper patterns to each other.

The contact hole includes a first sidewall having a an undercut under the intermediate pattern and a second sidewall portion facing the first sidewall portion in a horizontal direction. The upper pattern is broken under the active layer and is continuous at the second sidewall portion. The second sidewall portion is substantially smooth or has a slight step portion that is smaller than a step portion of the first sidewall portion. Therefore, the upper pattern can be stably formed inside the contact hole for connection to the lower pattern and breaking of the upper pattern can be prevented.

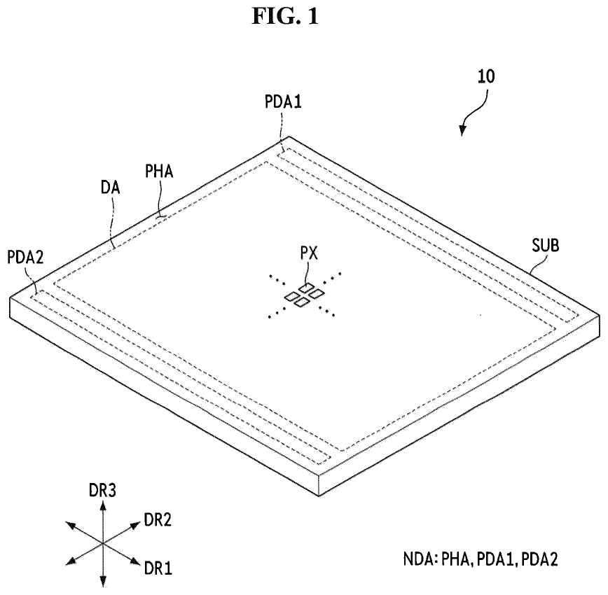

FIG. 1 is a perspective view of a display device 10 according to an embodiment.

Referring to FIG. 1, the display device 10 is a device for displaying at least one moving image and/or still image and may be used as a display screen in various electronic devices. For example, the display device 10 may be used as a display screen in portable electronic devices such as mobile phones, smartphones, tablet personal computers (PCs), smart watches, watch phones, mobile communication terminals, electronic notebooks, electronic books, portable multimedia players (PMPs), navigation devices and ultra-mobile PCs (UMPCs), as well as in various electronic devices such as televisions, notebook computers, monitors, billboards and Internet of things (IoT) devices. In addition, the display device 10 may be applied to other electronic devices such as virtual reality (VR) devices and augmented reality (AR) devices. However, embodiments of the present disclosure are not necessarily limited thereto and the display device 10 may be applied to various other small-sized, medium-sized or large-sized electronic devices.

In an embodiment, the display device 10 may be a light emitting display device including a light emitting element. For example, in an embodiment the display device 10 may be a light emitting display device such as an organic light emitting display device including an organic light emitting diode, a quantum dot light emitting display device including a quantum dot light emitting layer, an inorganic light emitting display device including an inorganic semiconductor, or an ultrasmall light emitting display device including an ultrasmall light emitting diode such as a micro-or nano-light emitting diode. However, embodiments of the present disclosure are not necessarily limited thereto. For example, the display device 10 may also be a display device of a type other than a light emitting display device.

Embodiments in which the display device 10 is an organic light emitting display device are disclosed below for economy of explanation. However, the display device 10 according to embodiments is not necessarily limited to an organic light emitting display device, and technical features of the embodiments to be described below may be applicable to other types of display devices.

The display device 10 may include a substrate SUB and pixels PX disposed on the substrate SUB.

The substrate SUB may be a base layer for manufacturing or providing the display device 10. In an embodiment, the substrate SUB may have a quadrangular shape in a plane defined by a first direction DR1 and a second direction DR2 (e.g., in a plan view). However, embodiments of the present disclosure are not necessarily limited thereto. For example, the substrate SUB may also have a polygonal shape other than the quadrangular shape, a circular shape, an oval shape, or an irregular shape in a plan view.

In FIG. 1, the first direction DR1 may indicate a horizontal direction (or a vertical direction) of the substrate SUB (or the display device 10), and the second direction DR2 may indicate a vertical direction (or a horizontal direction) of the substrate SUB. A third direction DR3 may indicate a thickness direction or a height direction of the substrate SUB. While the first to third directions DR1 to DR3 are shown as being perpendicular to each other, embodiments of the present disclosure are not necessarily limited thereto and the first to third directions DR1 to DR3 may intersect each other at various different angles.

The substrate SUB and the display device 10 including the substrate SUB may include a display area DA and a non-display area NDA. The display area DA may be an area where an image is displayed, and the non-display area NDA may be an area excluding the display area DA.

The display area DA may be an area where the pixels PX are located. For example, the pixels PX and lines (or portions of the lines) connected to the pixels PX may be located in the display area DA. In the description of embodiments, the term “connection” may include the meaning of electrical connection and/or physical connection.

The non-display area NDA may be located around the display area DA (e.g., in a plan view). In an embodiment, the non-display area NDA may include a first pad area PDA1, a second pad area PDA2, and a peripheral area PHA. Lines connected to the pixels PX (e.g., portions of lines extending from the display area DA to the non-display area NDA) and pads may be located in the non-display area NDA. In an embodiment, the non-display area NDA may further include a driving circuit area in which at least a portion of a driving circuit connected to the pixels PX is located.

Although an embodiment in which the display device 10 includes the first pad area PDA1 and the second pad area PDA2 disposed on different sides (e.g., upper and lower sides in the second direction DR2) of the display area DA is illustrated in FIG. 1, the number or positions of the pad areas PDA1 and PDA2 are not necessarily limited thereto. For example, the display device 10 may also include only one of the first pad area PDA1 and the second pad area PDA2 or may include three or more pad areas.

Each of the first pad area PDA1 and the second pad area PDA2 may include pads connected to an external circuit board. Driving signals and driving voltages for driving the pixels PX may be supplied from the circuit board to the display device 10 through the pads.

The peripheral area PHA may be an area excluding the first pad area PDA1 and the second pad area PDA2 from the non-display area NDA. The peripheral area PHA may surround the display area DA (e.g., in a plan view). The peripheral area PHA may or may not include a driving circuit area.

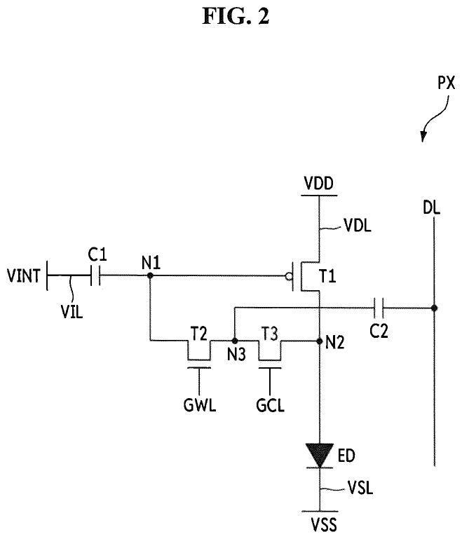

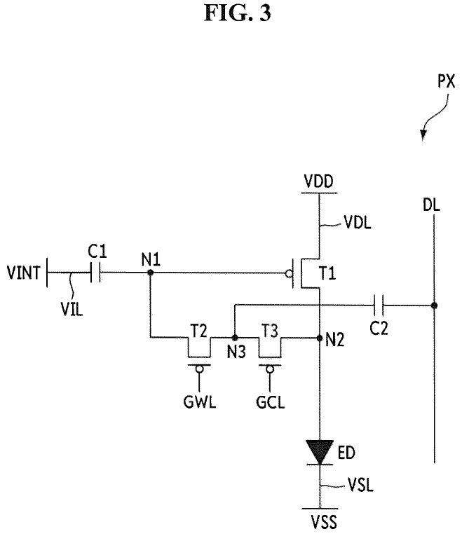

FIG. 2 is an equivalent circuit diagram of a pixel PX according to an embodiment. FIG. 3 is an equivalent circuit diagram of a pixel PX according to an embodiment. FIGS. 2 and 3 show differing embodiments in relation to second and third transistors T2 and T3.

Referring to FIGS. 2 and 3, a pixel PX according to an embodiment may be connected to signal lines including a first scan line GWL, a second scan line GCL and a data line DL and power lines including a first voltage line VDL, a second voltage line VSL and an initialization voltage line VIL (or an initialization signal line). The type or number of signal lines and power lines connected to the pixel PX may vary according to the type or structure of the pixel PX.

The first scan line GWL and the second scan line GCL may be connected between a scan driving circuit and the pixel PX. The first scan line GWL transmits a first scan signal output from the scan driving circuit to the pixel PX. In an embodiment, the first scan line GWL may be a write scan line, and the first scan signal may be a write scan signal. The second scan line GCL transmits a second scan signal output from the scan driving circuit to the pixel PX. In an embodiment, the second scan line GCL may be a control scan line, and the second scan signal may be a control scan signal. The scan driving circuit may be disposed on the substrate SUB or may be disposed on a circuit board connected to the display device 10 through signal pads (e.g., scan pads) located in at least one of the first pad area PDA1 and the second pad area PDA2.

The data line DL may be connected between a data driving circuit and the pixel PX. The data line DL transmits a data voltage output from the data driving circuit to the pixel PX. The data driving circuit may be disposed on the substrate SUB or may be disposed on a circuit board connected to the display device 10 through signal pads (e.g., data pads) located in at least one of the first pad area PDA1 and the second pad area PDA2.

The first voltage line VDL and the second voltage line VSL may be connected between a power supply circuit and the pixel PX. The first voltage line VDL and the second voltage line VSL transmit a first driving voltage VDD and a second driving voltage VSS output from the power supply circuit to the pixel PX. In an embodiment, the first driving voltage VDD may be a high-potential pixel voltage, and the second driving voltage VSS may be a low-potential pixel voltage. In an embodiment, the power supply circuit may be disposed on a circuit board connected to the display device 10 through power pads located in at least one of the first pad area PDA1 and the second pad area PDA2.

The initialization voltage line VIL may be connected between the power supply circuit or the scan driving circuit and the pixel PX. The initialization voltage line VIL transmits an initialization voltage VINT output from the power supply circuit or the scan driving circuit to the pixel PX.

The pixel PX may include a light emitting element ED and a pixel circuit electrically connected to the light emitting element ED.

The light emitting element ED may be connected between the pixel circuit and the second voltage line VSL. For example, a first electrode (e.g., an anode) of the light emitting element ED may be connected to the pixel circuit through a second node N2, and a second electrode (e.g., a cathode) of the light emitting element ED may be connected to the second voltage line VSL.

The light emitting element ED may emit light in response to a driving current supplied from the pixel circuit. In an embodiment, the light emitting element ED may be, but is not necessarily limited to, an organic light emitting diode. For example, the light emitting element ED may be an inorganic light emitting element, a quantum dot light emitting element, or other type of light emitting element.

The pixel circuit may be connected between the first voltage line VDL and the light emitting element ED. In addition, the pixel circuit may be further connected to the first scan line GWL, the second scan line GCL, the data line DL, and the initialization voltage line VIL.

The pixel circuit may include circuit elements including a transistor and a capacitor. The pixel circuit may be configured such that the pixel PX can emit light with a uniform luminance corresponding to a data voltage of each grayscale level. Accordingly, the pixel circuit may include a plurality of transistors and at least one capacitor. In an embodiment, the pixel circuit may include first, second and third transistors T1, T2 and T3 and first and second capacitors C1 and C2. The type or structure of the pixel circuit may vary according to embodiments.

In an embodiment, the pixel circuit may include different types of transistors, for example, a P-type transistor and an N-type transistor. For example, as illustrated in FIG. 2, the first transistor T1 may be a P-type transistor, and the second and third transistors T2 and T3 may be N-type transistors. In an embodiment, active layers of a P-type transistor and an N-type transistor may include different semiconductor materials from each other. For example, in an embodiment the active layer of the P-type transistor may include polysilicon, and the active layer of the N-type transistor may include an oxide semiconductor. In an embodiment, the active layers of the P-type transistor and the N-type transistor may include the same semiconductor material as each other.

In an embodiment, the pixel circuit may include transistors of the same type (e.g., P-type or N-type transistors). For example, as illustrated in FIG. 3, the first, second and third transistors T1, T2 and T3 may all be P-type transistors. In an embodiment, active layers of the first, second and third transistors T1, T2 and T3 may include, but are not necessarily limited to, polysilicon. For example, the type or material of each of the transistors included in the pixel circuit may vary according to embodiments.

Each of the first, second and third transistors T1, T2 and T3 may include a gate electrode, a source electrode (or a source region functioning as a source electrode), and a drain electrode (or a drain region functioning as a drain electrode). The source electrode and the drain electrode of each of the first, second and third transistors T1, T2 and T3 may be a first electrode and a second electrode other than a gate electrode of each of the first, second and third transistors T1, T2 and T3. Depending on the voltage applied to both terminals of each of the first, second and third transistors T1, T2 and T3 or the type (e.g., P-type or N-type transistor) of each of the first, second and third transistors T1, T2 and T3, one of the first electrode and the second electrode of each of the first, second and third transistors T1, T2 and T3 may be a source electrode, and the other may be a drain electrode.

The first transistor T1 may have the gate electrode connected to a first node N1, the source electrode connected to the first voltage line VDL, and the drain electrode connected to the second node N2. The second node N2 may be a node to which the first electrode (e.g., the anode) of the light emitting element ED is connected. In an embodiment, the first transistor T1 may control a driving current flowing to the light emitting element ED according to the voltage of the first node N1.

The second transistor T2 may have the gate electrode connected to the first scan line GWL, the source electrode connected to the first node N1, and the drain electrode connected to a third node N3. In an embodiment, the second transistor T2 may be turned on by the first scan signal of a gate-on voltage applied to the first scan line GWL to electrically connect the first node N1 and the third node N3.

The first node N1 may be connected to a first electrode of the first capacitor C1. In an embodiment, the voltage of the first node N1 may be initialized by the initialization voltage VINT applied to the initialization voltage line VIL which is connected to a second electrode of the first capacitor C1.

The third node N3 may be connected to a first electrode of the second capacitor C2. A voltage of the third node N3 may be changed to a voltage corresponding to the data voltage applied to the data line DL which is connected to a second electrode of the second capacitor C2.

The third transistor T3 may have the gate electrode connected to the second scan line GCL, the source electrode connected to the third node N3, and the drain electrode connected to the second node N2. In an embodiment, the third transistor T3 may be turned on by the second scan signal of a gate-on voltage applied to the second scan line GCL to electrically connect the third node N3 and the second node N2.

The first capacitor C1 may be connected between the first node N1 and the initialization voltage line VIL. For example, the first electrode of the first capacitor C1 may be connected to the first node N1, and the second electrode of the first capacitor C1 may be connected to the initialization voltage line VIL. Therefore, a potential difference between the first node N1 and the initialization voltage line VIL can be maintained. The voltage of the first node N1 may be initialized by the initialization voltage VINT applied to the initialization voltage line VIL.

The second capacitor C2 may be connected between the third node N3 and the data line DL. For example, the first electrode of the second capacitor C2 may be connected to the third node N3, and the second electrode of the second capacitor C2 may be connected to the data line DL. Therefore, a potential difference between the third node N3 and the data line DL can be maintained. The voltage of the third node N3 may be changed to the voltage corresponding to the data voltage applied to the data line DL.

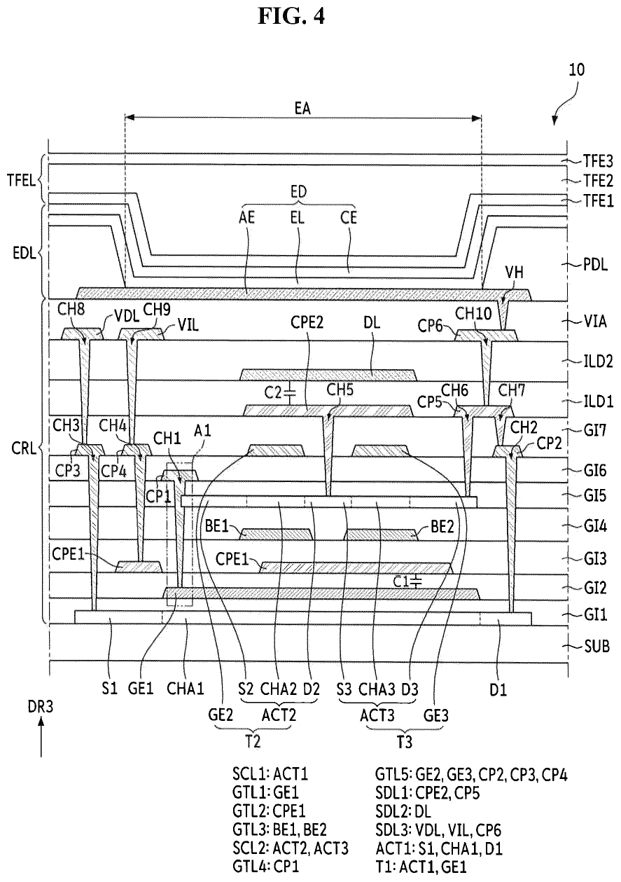

FIG. 4 is a cross-sectional view of the display device 10 according to an embodiment. For example, FIG. 4 shows a schematic cross-section of a portion (e.g., one pixel area located in the display area DA) of the display device 10 in which a pixel PX according to an embodiment is located.

Referring to FIG. 4, the display device 10 may include the substrate SUB and a circuit layer CRL disposed on the substrate SUB. The substrate SUB and the circuit layer CRL may form a display panel which implements a display screen as a core element of the display device 10. In an embodiment, the display device 10 may be a light emitting display device including a light emitting element ED, and the display device 10 (or the display panel) may further include a light emitting element layer EDL and an encapsulation layer TFEL. For example, in an embodiment the display panel of the display device 10 may include the substrate SUB and the circuit layer CRL, the light emitting element layer EDL and the encapsulation layer TFEL sequentially located (e.g., sequentially stacked along the third direction DR3) on the substrate SUB.

Although a structure in which a first transistor T1 of the circuit layer CRL is directly disposed on the substrate SUB is illustrated in FIG. 4, embodiments of the present disclosure are not necessarily limited thereto. For example, in some embodiments a buffer layer (or a barrier layer) may be formed on the substrate SUB, and the circuit layer CRL may be disposed on the buffer layer.

The substrate SUB may be a base layer for forming the display device 10. For example, the substrate SUB may form a support of the display panel including pixels PX.

The substrate SUB may be a substrate that includes an insulating material such as glass and has rigid characteristics. However, embodiments of the present disclosure are not necessarily limited thereto. For example, the substrate SUB may also be a flexible substrate that includes an insulating material such as polymer resin and can be bent, folded, rolled, etc. In an embodiment, the substrate SUB may be a semiconductor substrate, and the substrate SUB and a pixel circuit may be formed as a semiconductor circuit board including a complementary metal-oxide semiconductor (CMOS) circuit formed using a semiconductor process.

The circuit layer CRL may be disposed on (e.g., disposed directly thereon in the third direction DR3) the substrate SUB (or the buffer layer). The circuit layer CRL may include circuit elements included in each of the pixels PX (e.g., circuit elements included in each pixel circuit) and lines connected to the pixels PX. For example, in an embodiment the circuit layer CRL may include the first, second and third transistors T1, T2 and T3, the first and second capacitors C1 and C2, the first scan line GWL, the second scan line GCL, the data line DL, the first voltage line VDL, the second voltage line VSL and the initialization voltage line VIL of FIG. 2 or 3.

The circuit layer CRL may include at least one semiconductor layer, a plurality of conductive layers, and a plurality of insulating layers disposed on the substrate SUB. The semiconductor layer of the circuit layer CRL may include active layers of transistors located in the circuit layer CRL. The conductive layers of the circuit layer CRL may include conductive patterns included in or connected to circuit elements (e.g., transistors and capacitors) located in the circuit layer CRL. The conductive patterns may include electrodes of the circuit elements and connection patterns (e.g., bridge patterns) and/or lines connected to (e.g., electrically connected to) the circuit elements. The insulating layers of the circuit layer CRL may be located between the semiconductor layer and the conductive layers of the circuit layer CRL.

In an embodiment, the circuit layer CRL may include a plurality of semiconductor layers. For example, in an embodiment the circuit layer CRL may include a first semiconductor layer SCL1 including a first active layer ACT1 of the first transistor T1 and a second semiconductor layer SCL2 including second and third active layers ACT2 and ACT3 of the second and third transistors T2 and T3. The first semiconductor layer SCL1 and the second semiconductor layer SCL2 may be located in different layers from each other on the substrate SUB.

Since active layers of transistors included in a pixel PX are placed or distributed in the first semiconductor layer SCL1 and the second semiconductor layer SCL2, a pixel area can be utilized more efficiently, and the design of the circuit layer CRL can be optimized. For example, even if each pixel area is reduced as the resolution of the display device 10 increases, the transistors of the pixel PX can be appropriately placed in each pixel area. Accordingly, a high-resolution display device 10 can be easily manufactured.

In an embodiment, active layers located in different semiconductor layers may include the same semiconductor material or different semiconductor materials from each other. For example, in an embodiment the first active layer ACT1 may include polysilicon, and the second and third active layers ACT2 and ACT3 may include polysilicon or an oxide semiconductor.

In an embodiment, the conductive layers of the circuit layer CRL may include a first conductive layer GTL1, a second conductive layer GTL2, a third conductive layer GTL3, a fourth conductive layer GTL4, a fifth conductive layer GTL5, a sixth conductive layer SDL1, a seventh conductive layer SDL2, and an eighth conductive layer SDL3 sequentially disposed on the substrate SUB along the third direction DR3.

In an embodiment, the insulating layers of the circuit layer CRL may include a first insulating layer GI1, a second insulating layer GI2, a third insulating layer GI3, a fourth insulating layer GI4, a fifth insulating layer GI5, a sixth insulating layer GI6, a seventh insulating layer GI7, an eighth insulating layer ILD1, a ninth insulating layer ILD2, and a tenth insulating layer VIA sequentially disposed on the substrate SUB along the third direction DR3.

The structure of the circuit layer CRL may vary according to embodiments. For example, the numbers, types and/or positions of semiconductor layers (or a semiconductor layer), conductive layers, and insulating layers included in the circuit layer CRL and the numbers, types and/or shapes of patterns included in the semiconductor layers, conductive layers and insulating layers may vary according to the design structure of pixel circuits and lines.

The first semiconductor layer SCL1 may be disposed on (e.g., disposed directly thereon in the third direction DR3) the substrate SUB (or the buffer layer). The first semiconductor layer SCL1 may include semiconductor patterns including a semiconductor material (e.g., polysilicon, amorphous silicon, an oxide semiconductor, or other semiconductor materials). In an embodiment, the semiconductor patterns of the first semiconductor layer SCL1 may include polysilicon. In an embodiment, the first semiconductor layer SCL1 may include the first active layer ACT1 included in the first transistor T1 of each pixel PX.

In an embodiment, the first active layer ACT1 may include a first channel region CHA1, a first source region S1, and a first drain region D1. The first channel region CHA1 may overlap a first gate electrode GE1 included in the first transistor T1. The first channel region CHA1 may form a channel in response to a voltage applied to the first gate electrode GE1. The first source region S1 and the first drain region D1 may be disposed at respective sides of the first channel region CHA1. The first source region S1 and the first drain region D1 may have higher conductivity than the first channel region CHA1. For example, the carrier concentration of the first source region S1 and the first drain region D1 may be higher than the carrier concentration of the first channel region CHA1.

In an embodiment, the first source region S1 may be electrically connected to the first voltage line VDL through a third conductive pattern CP3 (or a first source electrode included in the first transistor T1). The first drain region D1 may be electrically connected to a first electrode AE of a light emitting element ED and a third drain region D3 of the third transistor T3 through at least one conductive pattern including a second conductive pattern CP2 (or a first drain electrode included in the first transistor T1).

The first insulating layer GI1 may be disposed on (e.g., disposed directly thereon) the substrate SUB and the first semiconductor layer SCL1 and may cover the semiconductor patterns of the first semiconductor layer SCL1. For example, the first insulating layer GI1 may cover the first active layer ACT1.

The first conductive layer GTL1 may be disposed on the first insulating layer GI1 (e.g., disposed directly thereon in the third direction DR3). The first conductive layer GTL1 may include conductive patterns including a conductive material. For example, the first conductive layer GTL1 may include the first gate electrode GE1 included in the first transistor T1 of each pixel PX. In an embodiment, the first gate electrode GE1 may be formed integrally with the first electrode of the first capacitor C1. For example, in an embodiment the first gate electrode GE1 may overlap (e.g., in the third direction DR3) a first capacitor electrode CPE1, and the first capacitor C1 may be formed by the first gate electrode GE1 and the first capacitor electrode CPE1. The first gate electrode GE1 and the first capacitor electrode CPE1 may form the first electrode and the second electrode of the first capacitor C1, respectively.

The second insulating layer GI2 may be disposed on (e.g., disposed directly thereon) the first insulating layer GI1 and the first conductive layer GTL1 and may cover the conductive patterns of the first conductive layer GTL1. For example, the second insulating layer GI2 may cover the first gate electrode GE1.

The second conductive layer GTL2 may be disposed on the second insulating layer GI2 (e.g., disposed directly thereon in the third direction DR3). The second conductive layer GTL2 may include conductive patterns including a conductive material. For example, the second conductive layer GTL2 may include the first capacitor electrode CPE1 overlapping the first gate electrode GE1 of each pixel PX. The first capacitor electrode CPE1 shown as being separated into two patterns in FIG. 4 may be a single electrode when seen in plan view.

The third insulating layer GI3 may be disposed on (e.g., disposed directly thereon) the second insulating layer GI2 and the second conductive layer GTL2 and may cover the conductive patterns of the second conductive layer GTL2. For example, the third insulating layer GI3 may cover the first capacitor electrode CPE1.

The third conductive layer GTL3 may be disposed on the third insulating layer GI3 (e.g., disposed directly thereon in the third direction DR3). The third conductive layer GTL3 may include conductive patterns including a conductive material. For example, in an embodiment the third conductive layer GTL3 may include a first bottom electrode BE1 and a second bottom electrode BE2 of each pixel PX. The first bottom electrode BE1 and the second bottom electrode BE2 may overlap (e.g., in the third direction DR3) the second and third active layers ACT2 and ACT3 included in the second and third transistors T2 and T3 of each pixel PX. For example, in an embodiment the first bottom electrode BE1 may overlap a second channel region CHA2 included in the second active layer ACT2, and the second bottom electrode BE2 may overlap a third channel region CHA3 included in the third active layer ACT3. In an embodiment, the first bottom electrode BE1 may be electrically connected to a second gate electrode GE2 of the second transistor T2 in an unillustrated area, but embodiments of the present disclosure are not necessarily limited thereto. When the first bottom electrode BE1 and the second gate electrode GE2 are connected, the second transistor T2 may have a dual-gate structure, and the first bottom electrode BE1 may be utilized as a back-gate electrode for adjusting the characteristics of the second transistor T2. In an embodiment, the second bottom electrode BE2 may be electrically connected to a third gate electrode GE3 of the third transistor T3 in an unillustrated area, but embodiments of the present disclosure are not necessarily limited thereto. When the second bottom electrode BE2 and the third gate electrode GE3 are connected, the third transistor T3 may have a dual-gate structure, and the second bottom electrode BE2 may be utilized as a back-gate electrode for adjusting the characteristics of the third transistor T3.

The fourth insulating layer GI4 may be disposed on (e.g., disposed directly thereon) the third insulating layer GI3 and the third conductive layer GTL3 and may cover the conductive patterns of the third conductive layer GTL3. For example, the fourth insulating layer GI4 may cover the first bottom electrode BE1 and the second bottom electrode BE2.

The second semiconductor layer SCL2 may be disposed on the fourth insulating layer GI4 (e.g., disposed directly thereon in the third direction DR3). In an embodiment, the second semiconductor layer SCL2 may include semiconductor patterns including a semiconductor material (e.g., polysilicon, amorphous silicon, an oxide semiconductor, or other semiconductor materials). In an embodiment, the semiconductor patterns of the second semiconductor layer SCL2 may include polysilicon or an oxide semiconductor. In an embodiment, the second semiconductor layer SCL2 may include the second active layer ACT2 and the third active layer ACT3 included in the second transistor T2 and the third transistor T3 of each pixel PX. In an embodiment, the second active layer ACT2 and the third active layer ACT3 may be formed integrally with each other. For example, a second drain region D2 and a third source region S3 may be formed integrally as one region.

The second active layer ACT2 may include the second channel region CHA2, a second source region S2, and the second drain region D2. The second channel region CHA2 may overlap (e.g., in the third direction DR3) the second gate electrode GE2 included in the second transistor T2. The second channel region CHA2 may form a channel in response to a voltage applied to the second gate electrode GE2. The second source region S2 and the second drain region D2 may be disposed at respective sides of the second channel region CHA2. The second source region S2 and the second drain region D2 may have higher conductivity than the second channel region CHA2.

In an embodiment, at least a portion of the second active layer ACT2 including an end may overlap the first gate electrode GE1 (e.g., in the third direction DR3). In an embodiment, the end of the second active layer ACT2 may overlap the first gate electrode GE1 and a first conductive pattern CP1 and may be electrically connected to the first conductive pattern CP1 by a first contact hole CH1.

The third active layer ACT3 may include the third channel region CHA3, the third source region S3, and the third drain region D3. The third channel region CHA3 may overlap the third gate electrode GE3 included in the third transistor T3 (e.g., in the third direction DR3). The third channel region CHA3 may form a channel in response to a voltage applied to the third gate electrode GE3. The third source region S3 and the third drain region D3 may be disposed on respective sides of the third channel region CHA3. The third source region S3 and the third drain region D3 may have higher conductivity than the third channel region CHA3.

In an embodiment, the second source region S2 may be electrically connected to the first gate electrode GE1 through the first conductive pattern CP1 (or a second source electrode included in the second transistor T2). In an embodiment, the second drain region D2 may be integrated with the third source region S3. The second drain region D2 and the third source region S3 may be electrically connected to a second capacitor electrode CPE2 (or a second drain electrode included in the second transistor T2 and a third source electrode included in the third transistor T3). The third drain region D3 may be electrically connected to the first electrode AE of the light emitting element ED through at least one conductive pattern including a fifth conductive pattern CP5 (or a third drain electrode included in the third transistor T3).

The fifth insulating layer GI5 may be disposed on the fourth insulating layer GI4 (e.g., disposed directly thereon in the third direction DR3) and the second semiconductor layer SCL2 and may cover the semiconductor patterns of the second semiconductor layer SCL2. For example, the fifth insulating layer GI5 may cover the second active layer ACT2 and the third active layer ACT3.

The fourth conductive layer GTL4 may be disposed on the fifth insulating layer GI5 (e.g., disposed directly thereon in the third direction DR3). The fourth conductive layer GTL4 may include conductive patterns including a conductive material. For example, the fourth conductive layer GTL4 may include the first conductive pattern CP1 of each pixel PX.

The first conductive pattern CP1 may be electrically connected to the first gate electrode GE1 included in the first transistor T1 and the second active layer ACT2 included in the second transistor T2. For example, the first conductive pattern CP1 may electrically connect the first gate electrode GE1 and the second source region S2 to each other. In an embodiment, the first conductive pattern CP1 may be a connection pattern that forms the first node N1. Alternatively, the first conductive pattern CP1 may be the source electrode of the second transistor T2 and may be considered as an element included in the second transistor T2.

In an embodiment, the first conductive pattern CP1 may be connected to the first gate electrode GE1 and the second source region S2 by penetrating a plurality of insulating layers located between the first conductive layer GTL1 and the fourth conductive layer GTL4. For example, the first conductive pattern CP1 may be electrically connected to the first gate electrode GE1 and the second source region S2 by the first contact hole CH1 formed in the second, third, fourth and fifth insulating layers GI2, GI3, GI4 and GI5.

In an embodiment, the first contact hole CH1 may be formed to penetrate the second, third, fourth and fifth insulating layers GI2, GI3, GI4 and GI5 all at once and may expose a portion of an upper surface of the first gate electrode GE1 and an end of the second active layer ACT2 (e.g., a left end where the second source region S2 is located). The shape of the first contact hole CH1 is not necessarily limited to the shape illustrated in FIG. 4, and the shape or size of the first contact hole CH1 may vary according to embodiments. In addition, although the first conductive pattern CP1 entirely fills the first contact hole CH1 in FIG. 4, embodiments are not necessarily limited thereto. For example, the first conductive pattern CP1 may entirely or partially fill the first contact hole CH1.

In an embodiment, the first conductive pattern CP1 may directly contact the first gate electrode GE1 at a bottom portion of the first contact hole CH1 and may contact a side surface of the second source region S2 at a sidewall portion (e.g., a right sidewall portion) of the first contact hole CH1. For example, in an embodiment the first conductive pattern CP1 and the second source region S2 may be connected in a side-contact structure at a sidewall of the first contact hole CH1.

According to an embodiment, the first conductive pattern CP1 may be simultaneously connected to the first gate electrode GE1 and the second source region S2 through one first contact hole CH1. Accordingly, the number of contact holes located in each pixel area can be reduced or minimized, and each pixel area can be efficiently utilized.

The sixth insulating layer GI6 may be disposed on (e.g., disposed directly thereon) the fifth insulating layer GI5 and the fourth conductive layer GTL4 and may cover the conductive patterns of the fourth conductive layer GTL4. For example, the sixth insulating layer GI6 may cover the first conductive pattern CP1.

The fifth conductive layer GTL5 may be disposed on the sixth insulating layer GI6 (e.g., disposed directly thereon in the third direction DR3). The fifth conductive layer GTL5 may include conductive patterns including a conductive material. For example, the fifth conductive layer GTL5 may include the second and third gate electrodes GE2 and GE3 included in the second and third transistors T2 and T3 of each pixel PX. The second gate electrode GE2 may be electrically connected to the first scan line GWL of FIG. 2 or 3. In an embodiment, the second gate electrode GE2 and the first scan line GWL may be formed integrally, but embodiments of the present disclosure are not necessarily limited thereto. The third gate electrode GE3 may be electrically connected to the second scan line GCL of FIG. 2 or 3. In an embodiment, the third gate electrode GE3 and the second scan line GCL may be formed integrally, but embodiments of the present disclosure are not necessarily limited thereto.

In an embodiment, the fifth conductive layer GTL5 may further include at least one conductive pattern that forms another electrode constituting at least one circuit element included in each pixel PX or a connection pattern electrically connected to the at least one circuit element. For example, the fifth conductive layer GTL5 may further include second, third and fourth conductive patterns CP2, CP3 and CP4 of each pixel PX.

The second conductive pattern CP2 may be electrically connected to a region of the first active layer ACT1 by penetrating a plurality of insulating layers located between the first semiconductor layer SCL1 and the fifth conductive layer GTL5 (e.g., in the third direction DR3). For example, the second conductive pattern CP2 may be electrically connected to the first drain region D1 through a second contact hole CH2 formed in the first insulating layer GI1, the second insulating layer GI2, the third insulating layer GI3, the fourth insulating layer GI4, the fifth insulating layer GI5 and the sixth insulating layer GI6 to expose a portion of the first drain region D1. In an embodiment, the second conductive pattern CP2 may be the drain electrode of the first transistor T1 and may be considered as an element included in the first transistor T1.

The third conductive pattern CP3 may be electrically connected to another region of the first active layer ACT1 by penetrating a plurality of insulating layers located between the first semiconductor layer SCL1 and the fifth conductive layer GTL5 (e.g., in the third direction DR3). For example, the third conductive pattern CP3 may be electrically connected to the first source region S1 through a third contact hole CH3 formed in the first insulating layer GI1, the second insulating layer GI2, the third insulating layer GI3, the fourth insulating layer GI4, the fifth insulating layer GI5 and the sixth insulating layer GI6 to expose a portion of the first source region S1. In an embodiment, the third conductive pattern CP3 may be the source electrode of the first transistor T1 and may be considered as an element included in the first transistor T1.

The fourth conductive pattern CP4 may be electrically connected to the first capacitor electrode CPE1 by penetrating a plurality of insulating layers located between the second conductive layer GTL2 and the fifth conductive layer GTL5 (e.g., in the third direction DR3). For example, the fourth conductive pattern CP4 may be electrically connected to the first capacitor electrode CPE1 through a fourth contact hole CH4 formed in the third insulating layer GI3, the fourth insulating layer GI4, the fifth insulating layer GI5 and the sixth insulating layer GI6 to expose a portion of the first capacitor electrode CPE1. In an embodiment, the fourth conductive pattern CP4 may be a connection pattern that connects the first capacitor electrode CPE1 and the initialization voltage line VIL.

The seventh insulating layer GI7 may be disposed on (e.g., disposed directly thereon) the sixth insulating layer GI6 and the fifth conductive layer GTL5 and may cover the conductive patterns of the fifth conductive layer GTL5. For example, the seventh insulating layer GI7 may cover the second and third gate electrodes GE2 and GE3 and the second, third and fourth conductive patterns CP2, CP3 and CP4.

The sixth conductive layer SDL1 may be disposed on the seventh insulating layer GI7 (e.g., disposed directly thereon in the third direction DR3). The sixth conductive layer SDL1 may include conductive patterns including a conductive material. For example, the sixth conductive layer SDL1 may include the second capacitor electrode CPE2 of each pixel PX. The second capacitor electrode CPE2 overlaps (e.g., in the third direction DR3) the data line DL (or the second electrode of the second capacitor C2 electrically connected to the data line DL) connected to each pixel PX, and the second capacitor C2 may be formed by the second capacitor electrode CPE2 and the data line DL. The second capacitor electrode CPE2 and the data line DL may form the first electrode and the second electrode of the second capacitor C2, respectively.

The second capacitor electrode CPE2 may be electrically connected to a region of the second active layer ACT2 and the third active layer ACT3 by penetrating a plurality of insulating layers located between the second semiconductor layer SCL2 and the sixth conductive layer SDL1 (e.g., in the third direction DR3). For example, the second capacitor electrode CPE2 may be electrically connected to the second drain region D2 and the third source region S3 through a fifth contact hole CH5 formed in the fifth insulating layer GI5, the sixth insulating layer GI6 and the seventh insulating layer GI7 to expose a portion of the second drain region D2 and the third source region S3. In an embodiment, the second capacitor electrode CPE2 may be the drain electrode of the second transistor T2 and the source electrode of the third transistor T3 and may be considered as an element included in the second transistor T2 and the third transistor T3. For example, the second capacitor C2, the second transistor T2, and the third transistor T3 may share one electrode which is commonly connected to the third node N3.

In an embodiment, the sixth conductive layer SDL1 may further include at least one conductive pattern that forms another electrode constituting at least one circuit element included in each pixel PX or a connection pattern electrically connected to the at least one circuit element. For example, the sixth conductive layer SDL1 may further include the fifth conductive pattern CP5 of each pixel PX.

The fifth conductive pattern CP5 may be electrically connected to another region of the third active layer ACT3 by penetrating a plurality of insulating layers located between the second semiconductor layer SCL2 and the sixth conductive layer SDL1. For example, in an embodiment the fifth conductive pattern CP5 may be electrically connected to the third drain region D3 through a sixth contact hole CH6 formed in the fifth insulating layer GI5, the sixth insulating layer GI6 and the seventh insulating layer GI7 to expose a portion of the third drain region D3. In an embodiment, the fifth conductive pattern CP5 may be the drain electrode of the third transistor T3 and may be considered as an element included in the third transistor T3.

In addition, the fifth conductive pattern CP5 may be electrically connected to the second conductive pattern CP2 by penetrating an insulating layer located between the fifth conductive layer GTL5 and the sixth conductive layer SDL1 (e.g., in the third direction DR3). For example, the fifth conductive pattern CP5 may be electrically connected to the second conductive pattern CP2 through a seventh contact hole CH7 formed in the seventh insulating layer GI7 to expose a portion of the second conductive pattern CP2.

The eighth insulating layer ILD1 may be disposed on (e.g., disposed directly thereon) the seventh insulating layer GI7 and the sixth conductive layer SDL1 and may cover the conductive patterns of the sixth conductive layer SDL1. For example, the eighth insulating layer ILD1 may cover the second capacitor electrode CPE2 and the fifth conductive pattern CP5.

The seventh conductive layer SDL2 may be disposed on the eighth insulating layer ILD1 (e.g., disposed directly thereon in the third direction DR3). The seventh conductive layer SDL2 may include conductive patterns including a conductive material. For example, the seventh conductive layer SDL2 may include the data line DL (or the second electrode of the second capacitor C2) connected to each pixel PX. In an embodiment, the data line DL may form the second capacitor C2 together with the second capacitor electrode CPE2.

The ninth insulating layer ILD2 may be disposed on (e.g., disposed directly thereon) the eighth insulating layer ILD1 and the seventh conductive layer SDL2 and may cover the conductive patterns of the seventh conductive layer SDL2. For example, the ninth insulating layer ILD2 may cover the data line DL.

The eighth conductive layer SDL3 may be disposed on the ninth insulating layer ILD2. The eighth conductive layer SDL3 may include conductive patterns including a conductive material. For example, in an embodiment the eighth conductive layer SDL3 may include the first voltage line VDL and the initialization voltage line VIL. In an embodiment, the eighth conductive layer SDL3 may further include a sixth conductive pattern CP6 of each pixel PX.

The first voltage line VDL may be electrically connected to the third conductive pattern CP3 by penetrating a plurality of insulating layers located between the fifth conductive layer GTL5 and the eighth conductive layer SDL3 (e.g., in the third direction DR3). For example, in an embodiment the first voltage line VDL may be electrically connected to the third conductive pattern CP3 through an eighth contact hole CH8 formed in the seventh insulating layer GI7, the eighth insulating layer ILD1 and the ninth insulating layer ILD2 to expose a portion of the third conductive pattern CP3. The first voltage line VDL may be electrically connected to the first source region S1 through the third conductive pattern CP3.

The initialization voltage line VIL may be electrically connected to the fourth conductive pattern CP4 by penetrating a plurality of insulating layers located between the fifth conductive layer GTL5 and the eighth conductive layer SDL3 (e.g., in the third direction DR3). For example, in an embodiment the initialization voltage line VIL may be electrically connected to the fourth conductive pattern CP4 through a ninth contact hole CH9 formed in the seventh insulating layer GI7, the eighth insulating layer ILD1 and the ninth insulating layer ILD2 to expose a portion of the fourth conductive pattern CP4. The initialization voltage line VIL may be electrically connected to the first capacitor electrode CPE1 through the fourth conductive pattern CP4.

The sixth conductive pattern CP6 may be electrically connected to the fifth conductive pattern CP5 by penetrating a plurality of insulating layers located between the sixth conductive layer SDL1 and the eighth conductive layer SDL3 (e.g., in the third direction DR3). For example, in an embodiment the sixth conductive pattern CP6 may be electrically connected to the fifth conductive pattern CP5 through a tenth contact hole CH10 formed in the eighth insulating layer ILD1 and the ninth insulating layer ILD2 to expose a portion of the fifth conductive pattern CP5. The sixth conductive pattern CP6 may be electrically connected to the third drain region D3 and the second conductive pattern CP2 through the fifth conductive pattern CP5. The sixth conductive pattern CP6 may be electrically connected to the first drain region D1 through the second conductive pattern CP2. In an embodiment, the sixth conductive pattern CP6 may be a connection pattern that forms the second node N2.

In an embodiment, the eighth conductive layer SDL3 may further include the second voltage line VSL of FIG. 2 or 3. However, embodiments of the present disclosure are not necessarily limited thereto, and the second voltage line VSL may also be located in another conductive layer included in the circuit layer CRL. The second voltage line VSL may be electrically connected to a second electrode CE of the light emitting element ED inside the display area DA and/or around the display area DA.

The tenth insulating layer VIA may be disposed on (e.g., disposed directly thereon) the ninth insulating layer ILD2 and the eighth conductive layer SDL3 and may cover the conductive patterns of the eighth conductive layer SDL3. For example, in an embodiment the tenth insulating layer VIA may cover the first voltage line VDL, the initialization voltage line VIL, and the sixth conductive pattern CP6.

Although a structure in which the light emitting element layer EDL is located directly on the tenth insulating layer VIA is illustrated in FIG. 4, embodiments of the present disclosure are not necessarily limited thereto. For example, a circuit layer CRL according to an embodiment may further include a ninth conductive layer which is disposed on the tenth insulating layer VIA and includes a seventh conductive pattern electrically connected to the sixth conductive pattern CP6 through a contact hole penetrating the tenth insulating layer VIA and an eleventh insulating layer which covers patterns of the ninth conductive layer. In this embodiment, the light emitting element layer EDL may be disposed on the eleventh insulating layer, and the first electrode AE of the light emitting element ED may be electrically connected to the seventh conductive pattern through a contact hole penetrating the eleventh insulating layer. For example, the first electrode AE of the light emitting element ED may be electrically connected to the sixth conductive pattern CP6 through the seventh conductive pattern. In addition, the number of conductive layers and insulating layers that can be included in the circuit layer CRL may vary according to embodiments.

The conductive patterns (e.g., conductive patterns that form electrodes, connection patterns (e.g., the first through sixth conductive patterns CP1 through CP6), and/or lines) included in each of the conductive layers of the circuit layer CRL may have a single-layer or multilayer structure including at least one conductive material. For example, in an embodiment each of the conductive patterns included in the first conductive layer GTL1, the second conductive layer GTL2, the third conductive layer GTL3, the fourth conductive layer GTL4, the fifth conductive layer GTL5, the sixth conductive layer SDL1, the seventh conductive layer SDL2, and the eighth conductive layer SDL3 may include at least one of molybdenum (Mo), aluminum (Al), chromium (Cr), gold (Au), silver (Ag), titanium (Ti), nickel (Ni), neodymium (Nd), copper (Cu) and other metals, an alloy thereof, or other conductive materials and may have a single-layer or multilayer structure. At least two of the conductive layers of the circuit layer CRL may include the same material or different materials.

Each of the insulating layers of the circuit layer CRL may include at least one insulating material and may have a single-layer or multilayer structure. For example, each of the first insulating layer GI1, the second insulating layer GI2, the third insulating layer GI3, the fourth insulating layer GI4, the fifth insulating layer GI5, the sixth insulating layer GI6, the seventh insulating layer GI7, the eighth insulating layer ILD1, the ninth insulating layer ILD2, and the tenth insulating layer VIA may include an organic insulating material and/or an inorganic insulating material and may have a single-layer or multilayer structure. At least two of the insulating layers of the circuit layer CRL may include the same material or different materials from each other.

In an embodiment, each of the first insulating layer GI1, the second insulating layer GI2, the third insulating layer GI3, the fourth insulating layer GI4, the fifth insulating layer GI5, the sixth insulating layer GI6, the seventh insulating layer GI7, the eighth insulating layer ILD1, and the ninth insulating layer ILD2 may be a single or multilayer inorganic insulating layer including an inorganic insulating material (e.g., silicon nitride (e.g., Si₃N₄ or SiNₓ), silicon oxide (e.g., SiO₂ or SiOₓ), silicon oxynitride (e.g., SiON), titanium oxide, aluminum oxide, or other inorganic insulating materials). Accordingly, the circuit elements located in the circuit layer CRL can be appropriately protected, and a thickness of the circuit layer CRL can be reduced or minimized.

In an embodiment, the tenth insulating layer VIA may include an organic insulating material (e.g., acryl resin, epoxy resin, phenolic resin, polyamide resin, polyimide resin, or other organic insulating materials). Accordingly, the upper surface of the tenth insulating layer VIA may be substantially flat. However, embodiments are not limited thereto. For example, in an embodiment after the tenth insulating layer VIA is formed using an inorganic insulating material, it may be planarized by a planarization process. The material and/or structure of each of the insulating layers of the circuit layer CRL may vary according to embodiments.

In an embodiment, the number of semiconductor layers and/or conductive layers included in the circuit layer CRL may be increased according to the securable design area of the circuit layer CRL to appropriately arrange the circuit elements of the circuit layer CRL within the circuit layer CRL and secure a space between adjacent conductive patterns. Accordingly, even in a high-resolution display device having a small pixel size, circuit elements of a pixel PX can be appropriately arranged in each pixel area.

In an embodiment, when the number of semiconductor layers and/or conductive layers included in the circuit layer CRL increases, depths of contact holes included in the circuit layer CRL may increase, or at least one contact hole penetrating a plurality of insulating layers may be separated into a plurality of contact holes penetrating different insulating layers. In FIG. 4, the contact holes have substantially the same or similar widths as each other and are completely filled with the conductive patterns, respectively. However, embodiments of the present disclosure are not necessarily limited thereto and the size and/or shape of each of the contact holes and the conductive patterns may vary according to embodiments. In addition, each conductive pattern connected to a pattern under a corresponding contact hole through the contact hole may completely or partially fill the contact hole.

In an embodiment, three or more patterns located in different layers from each other may be simultaneously connected by one contact hole. For example, the first gate electrode GE1, the second active layer ACT2 (e.g., the second source region S2 of the second active layer ACT2), and the first conductive pattern CP1 may be electrically connected to each other by one first contact hole CH1. Accordingly, the number and/or width of contact holes located in the circuit layer CRL can be reduced or minimized, and the effectiveness of the design structure of the circuit layer CRL can be increased.

The light emitting element layer EDL may be disposed on the circuit layer CRL (e.g., in the third direction DR3) and may be located in the display area DA. For example, the light emitting element layer EDL may be disposed on the circuit layer CRL in the display area DA.

The light emitting element layer EDL may include a pixel defining layer PDL which defines an emission area EA of each pixel PX and a light emitting element ED located in the emission area EA of each pixel PX. In an embodiment, the light emitting element layer EDL may further include a spacer disposed on a portion of the pixel defining layer PDL.

The light emitting element ED may include the first electrode AE (e.g., an anode) and the second electrode CE (e.g., a cathode) facing each other and a light emitting layer EL located between the first electrode AE and the second electrode CE. In an embodiment, the first electrode AE, the light emitting layer EL, and the second electrode CE may be sequentially stacked on the circuit layer CRL along the third direction DR3.

In an embodiment, the light emitting element ED may further include at least one intermediate layer. For example, the light emitting element ED may further include a first intermediate layer (e.g., a hole layer including a hole transport layer) located between the first electrode AE and the light emitting layer EL and a second intermediate layer (e.g., an electron layer including an electron transport layer) located between the light emitting layer EL and the second electrode CE. In an embodiment, at least one intermediate layer may be a common layer formed over the entire display area DA.

Although FIG. 4 discloses an embodiment in which the light emitting element ED includes a single light emitting layer EL, embodiments are not necessarily limited thereto. For example, the light emitting element ED may be formed in a 2 or more tandem structure including at least two light emitting layers (e.g., the light emitting layer EL of FIG. 4 and an additional light emitting layer overlapping the light emitting layer EL) which overlap each other in the third direction DR3. In addition, the light emitting element ED may further include a charge generation layer located between the at least two light emitting layers. The light emitting layer EL may be formed as a common layer formed over the entire display area DA or may have a shape and/or size corresponding to that of the emission area EA of each pixel PX and may be individually located in each pixel area.

In an embodiment, the display device 10 may further include an optical layer disposed on the light emitting element layer EDL. The optical layer may include at least one of a color filter layer (e.g., a color filter layer including color filters corresponding to the colors of light emitted from the pixels PX) and a light conversion layer (e.g., a light conversion layer including wavelength conversion patterns which convert the colors or wavelengths of light emitted from the light emitting elements ED of at least some of the pixels PX). Accordingly, the colors or wavelengths of light emitted from the pixels PX can be appropriately controlled. The optical layer may be optionally provided in the display device 10 as needed. For example, the display device 10 may include at least one optical layer or may not include any optical layer depending on the type or shape of the light emitting elements ED or the structure of the light emitting element layer EDL.

The first electrode AE of the light emitting element ED may be disposed on the circuit layer CRL (e.g., in the third direction DR3). For example, the first electrode AE may be disposed on the tenth insulating layer VIA in each emission area EA.

The light emitting element ED may be electrically connected to at least one circuit element included in each pixel PX. For example, the light emitting element ED may be electrically connected to the first transistor T1. For example, in an embodiment the first electrode AE of the light emitting element ED may be electrically connected to the sixth conductive pattern CP6 through a via hole VH formed in the tenth insulating layer VIA and may be electrically connected to the first drain region D1 of the first transistor T1 and the third drain region D3 of the third transistor T3 through the sixth conductive pattern CP6, the fifth conductive pattern CP5 and the second conductive pattern CP2.

The first electrode AE of the light emitting element ED may include at least one conductive material and may be formed as a single layer or a multilayer. In an embodiment, the first electrode AE may include a reflective electrode layer including a metal material having high reflectivity.

The light emitting layer EL of the light emitting element ED may include a high molecular material or a low molecular material. Light emitted from the light emitting layer EL may provide the displayed image. In an embodiment, the light emitting layer EL may be provided for each pixel PX, and the light emitting layer EL of each pixel PX may emit visible light of a color or wavelength corresponding to the pixel PX. In an embodiment, the light emitting layer EL may be a common layer shared by pixels PX of different colors, and color filters and/or light conversion layers corresponding to the colors (or wavelengths) of light to be emitted from the pixels PX may be located in the emission areas EA of at least some of the pixels PX.

The second electrode CE of the light emitting element ED may include a conductive material. In an embodiment, the second electrode CE may be a common layer formed over the entire display area DA to cover the light emitting layer EL and the pixel defining layer PDL. In an embodiment, the second electrode CE may include a transparent conductive material (TCO) that can transmit light, such as indium tin oxide (ITO) or indium zinc oxide (IZO), or a semi-transmissive conductive material such as magnesium (Mg), silver (Ag) or an alloy of Mg and Ag.

The pixel defining layer PDL may have an opening corresponding to each emission area EA and may surround the emission areas EA (e.g., in a plan view). For example, in an embodiment the pixel defining layer PDL may be formed to cover edges (e.g., lateral edges) of the first electrode AE of the light emitting element ED and may include an opening that exposes the remaining portion (e.g., a central portion) of the first electrode AE. An area where the exposed first electrode AE and the light emitting layer EL overlap (or an area including the first electrode AE and the light emitting layer EL) may be defined as the emission area EA of each pixel PX.

In an embodiment, the pixel defining layer PDL may include an organic insulating material. For example, in an embodiment the pixel defining layer PDL may include polyacrylates resin, epoxy resin, phenolic resin, polyamides resin, polyimides resin, unsaturated polyesters resin, polyphenylenethers resin, polyphenylenesulfides resin, benzocyclobutene (BCB), or other organic insulating materials.

The encapsulation layer TFEL may be disposed on the light emitting element layer EDL (e.g., disposed directly thereon in the third direction DR3). In an embodiment, the encapsulation layer TFEL may cover the light emitting element layer EDL in the display area DA and may extend to the non-display area NDA to directly contact the circuit layer CRL. For example, the encapsulation layer TFEL may be located in the display area DA to cover the light emitting element layer EDL, and an end of the encapsulation layer TFEL may be located in a portion of the non-display area NDA which is adjacent to the display area DA. The encapsulation layer TFEL may block the penetration of oxygen or moisture into the light emitting element layer EDL and may alleviate electrical and/or physical impact on the circuit layer CRL and the light emitting element layer EDL.

In an embodiment, the encapsulation layer TFEL may be a multilayer. For example, in an embodiment the encapsulation layer TFEL may include a first inorganic encapsulation layer TFE1, an organic encapsulation layer TFE2, and a second inorganic encapsulation layer TFE3 sequentially disposed on the light emitting element layer EDL. In an embodiment, the encapsulation layer TFEL may also be replaced with an encapsulation member of another type, structure, and/or material. For example, the light emitting element layer EDL may be encapsulated using an upper substrate including an insulating material such as glass or a protective layer including a single or multilayer capping layer.

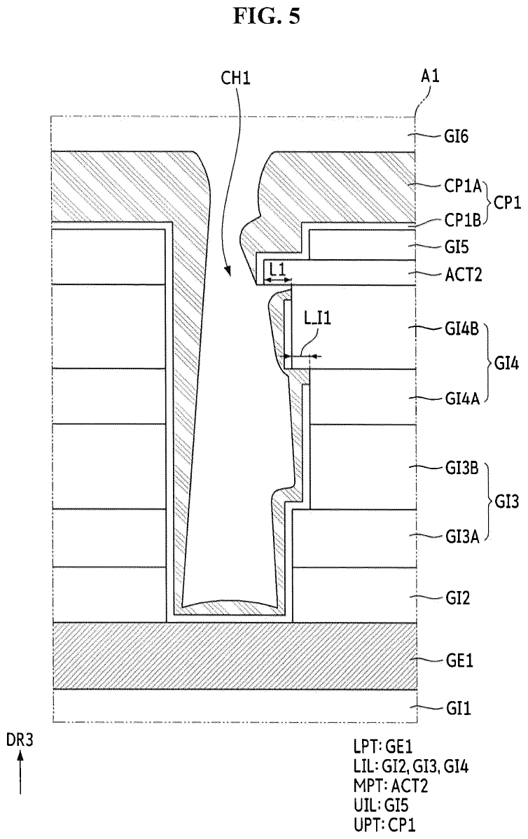

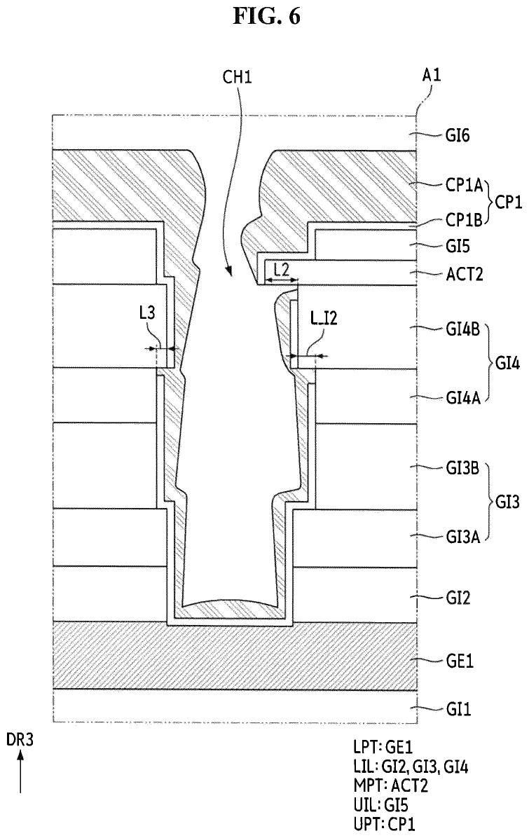

FIG. 5 is a cross-sectional view illustrating a contact hole according to an embodiment and a lower pattern, an active layer and an upper pattern connected through the contact hole. FIG. 6 is a cross-sectional view illustrating a contact hole according to an embodiment and a lower pattern, an active layer and an upper pattern connected through the contact hole. For example, FIGS. 5 and 6 show different embodiments of cross-sections of the first contact hole CH1 located in area A1 of FIG. 4 and the first gate electrode GE1, the second active layer ACT2 and the first conductive pattern CP1 connected through the first contact hole CH1.

Referring to FIGS. 5 and 6 in addition to FIG. 4, the first contact hole CH1 may overlap a portion of the first gate electrode GE1 and an end of the second active layer ACT2. The first contact hole CH1 may be formed to penetrate a plurality of insulating layers located between the first gate electrode GE1, the second active layer ACT2 and the first conductive pattern CP1 (e.g., in the third direction DR3) and may expose a portion of the first gate electrode GE1 and an end of the second active layer ACT2.

For example, in an embodiment the first contact hole CH1 may be formed to penetrate the second, third, fourth and fifth insulating layers GI2, GI3, GI4 and GI5 and may include a bottom portion exposing a portion (e.g., a portion of an upper surface) of the first gate electrode GE1, a first sidewall portion (e.g., a right sidewall portion) exposing an end (e.g., a left end) of the second active layer ACT2, and a second sidewall portion (e.g., a left sidewall portion) facing the first sidewall portion. For example the first sidewall portion and the second sidewall portion may face each other in a horizontal direction parallel to an upper surface of the substrate SUB. In an embodiment, the second active layer ACT2 may be disposed only at the first sidewall portion among the first sidewall portion and the second sidewall portion of the first contact hole CH1. Accordingly, the first sidewall portion and the second sidewall portion of the first contact hole CH1 may have different stacked structures from each other. In an embodiment, when an intermediate pattern MPT exposed at a sidewall portion of the first contact hole CH1 includes only the second active layer ACT2, the first sidewall portion and the second sidewall portion of the first contact hole CH1 may have the same stacked structure as each other except for the inclusion of the second active layer ACT2 in the first sidewall portion.

A portion of the first gate electrode GE1 which is exposed at the bottom portion of the first contact hole CH1 may be covered with the first conductive pattern CP1. For example, the first conductive pattern CP1 may directly contact the portion of the first gate electrode GE1 exposed at the bottom portion of the first contact hole CH1. The portion of the first gate electrode GE1 may or may not be etched during a process of forming the first contact hole CH1 or a subsequent post-treatment process. For example, a portion of the upper surface of the first gate electrode GE1 which is exposed by the first contact hole CH1 may not be etched as illustrated in FIG. 5 or may be etched by a certain thickness as illustrated in FIG. 6. However, even if a portion of the first gate electrode GE1 is etched as illustrated in FIG. 6, a thickness by which the first gate electrode GE1 is etched may be relatively small. Accordingly, the first gate electrode GE1 may include a shallow groove at the bottom portion of the first contact hole CH1.

An end of the second active layer ACT2 which is exposed at the first sidewall portion of the first contact hole CH1 may be connected to (e.g., directly connected thereto) the first conductive pattern CP1. For example, a side surface of the second active layer ACT2 where the second source region S2 is located may be exposed at the first sidewall portion of the first contact hole CH1. The side surface of the second active layer ACT2 may be covered with the first conductive pattern CP1.

The first conductive pattern CP1 may be located inside the first contact hole CH1. For example, a portion of the first conductive pattern CP1 may be located inside the first contact hole CH1, and the other portion of the first conductive pattern CP1 may be disposed on and/or around the first contact hole CH1. The first conductive pattern CP1 may contact (e.g., directly contact) the first gate electrode GE1 at the bottom portion of the first contact hole CH1 and may contact (e.g., directly contact) the second active layer ACT2 (e.g., an end of the second active layer ACT2 where the second source region S2 is located) at the first sidewall portion of the first contact hole CH1. Accordingly, the first conductive pattern CP1 may be electrically connected to the first gate electrode GE1 and the second active layer ACT2. The first conductive pattern CP1 may entirely or partially fill the first contact hole CH1.

In the description of embodiments, among patterns electrically connected to each other through each contact hole, a pattern located at a lowest position (e.g., closest to the substrate SUB in the third direction DR3) may be referred to as a “lower pattern,” and a pattern located at a highest position (e.g., farthest from the substrate SUB in the third direction DR3) may be referred to as an “upper pattern.” For example, among the first gate electrode GE1, the second active layer ACT2, and the first conductive pattern CP1 connected by the first contact hole CH1, the first gate electrode GE1 may be a lower pattern LPT, and the first conductive pattern CP1 may be an upper pattern UPT.

In an embodiment, when three or more patterns located in different layers are connected by one contact hole, a pattern located in an intermediate layer between the lower pattern LPT and the upper pattern UPT may be referred to as an “intermediate pattern.” For example, among the first gate electrode GE1, the second active layer ACT2 and the first conductive pattern CP1 connected by the first contact hole CH1, the second active layer ACT2 may be an intermediate pattern MPT and may be exposed at a sidewall portion of the first contact hole CH1.

In the description of embodiments, among insulating layers through which a contact hole passes to connect a pair or a group of the lower pattern LPT, the intermediate pattern MPT and the upper pattern UPT, insulating layers between the lower pattern LPT and the intermediate pattern MPT may be referred to as a “lower insulating layer,” and insulating layers between the intermediate pattern MPT and the upper pattern UPT may be referred to as an “upper insulating layer.” For example, among the second, third, fourth and fifth insulating layers GI2, GI3, GI4 and GI5 in which the first contact hole CH1 is formed, the second, third and fourth insulating layers GI2, GI3 and GI4 located between the first gate electrode GE1 and the second active layer ACT2 may be a lower insulating layer LIL, and the fifth insulating layer GI5 located between the second active layer ACT2 and the first conductive pattern CP1 may be an upper insulating layer UIL.

The lower insulating layer LIL and the upper insulating layer UIL may be sequentially stacked on the lower pattern LPT (e.g., in the third direction DR3). Each of the lower insulating layer LIL and the upper insulating layer UIL may include at least one insulating layer. For example, in an embodiment the lower insulating layer LIL may be disposed on the lower pattern LPT, the intermediate pattern MPT, such as the second active layer ACT2, may be disposed on the lower insulating layer LIL, the upper insulating layer UIL may be disposed on the intermediate pattern MPT and the upper pattern UPT may be disposed on the upper insulating layer UIL.

In an embodiment, the lower insulating layer LIL and the upper insulating layer UIL may include at least two types of insulating layers including different materials from each other. For example, the lower insulating layer LIL and the upper insulating layer UIL may include a plurality of insulating layers exposed at a sidewall portion of the first contact hole CH1, covered by the upper pattern UPT, and including different materials from each other. For example, in an embodiment the lower insulating layer LIL and the upper insulating layer UIL may include the second, third, fourth and fifth insulating layers GI2, GI3, GI4 and GI5 covered by the first conductive pattern CP1 at a sidewall portion of the first contact hole CH1 and including at least two types of insulating materials.

In an embodiment, the second, third, fourth and fifth insulating layers GI2, GI3, GI4 and GI5 may include at least one silicon oxide layer including silicon oxide and at least one silicon nitride layer including silicon nitride. In addition, each of the second, third, fourth and fifth insulating layers GI2, GI3, GI4 and GI5 may be formed as a single layer or a multilayer. The insulating layers that form the lower insulating layer LIL and the upper insulating layer UIL may be formed to have respective materials, structures, and/or thicknesses optimized to satisfy the characteristics required of the insulating layers and to secure the reliability of the circuit elements or lines located in the circuit layer CRL. For example, the insulating layers of the circuit layer CRL, including the lower insulating layer LIL and the upper insulating layer UIL, may be formed to have respective materials, structures, and/or thicknesses optimized to secure the characteristics of the circuit elements located in the circuit layer CRL and to appropriately block moisture penetration, etc.

In an embodiment, each of the second insulating layer GI2 and the fifth insulating layer GI5 may be a single layer. For example, in an embodiment the second insulating layer GI2 may be a single silicon nitride layer, and the fifth insulating layer GI5 may be a single silicon oxide layer. The material and/or structure of each of the second insulating layer GI2 and the fifth insulating layer GI5 may vary according to the characteristics required of each of the second insulating layer GI2 and the fifth insulating layer GI5.

In an embodiment, each of the third insulating layer GI3 and the fourth insulating layer GI4 may be a multilayer. For example, the third insulating layer GI3 may be a multilayer including a first layer GI3A including a silicon nitride layer and a second layer GI3B including a silicon oxide layer, and the fourth insulating layer GI4 may be a multilayer including a first layer GI4A including a silicon oxide layer and a second layer GI4B including a silicon nitride layer. In an embodiment, the first layer GI3A and the second layer GI3B of the third insulating layer GI3 may be sequentially disposed on the second insulating layer GI2, and the first layer GI4A and the second layer GI4B of the fourth insulating layer GI4 may be sequentially disposed on the third insulating layer GI3. In an embodiment, a thickness (e.g., length in the third direction DR3) of the first layer GI3A of the third insulating layer GI3 may be less than a thickness (e.g., length in the third direction DR3) of the second layer GI3B of the third insulating layer GI3, and a thickness (e.g., length in the third direction DR3) of the first layer GI4A of the fourth insulating layer GI4 may be less than a thickness (e.g., length in the third direction DR3) of the second layer GI4B of the fourth insulating layer GI4. The material, structure, and/or thickness of each of the third insulating layer GI3 and the fourth insulating layer GI4 may vary according to the characteristics required of each of the third insulating layer GI3 and the fourth insulating layer GI4.

In an embodiment, after the first contact hole CH1 is initially formed by etching the lower insulating layer LIL and the upper insulating layer UIL using dry etching or the like, a post-treatment process including buffered oxide etching using a buffered oxide etchant may be performed. Etch residues may be removed by the buffered oxide etching, and surfaces damaged in the dry etching process (e.g., surfaces of the first gate electrode GE1 and the second active layer ACT2 exposed by the first contact hole CH1) may be cleaned up.

In an embodiment in which the lower insulating layer LIL and the upper insulating layer UIL include a plurality of insulating layers including different materials from each other, etch selectivities of the insulating layers for the buffered oxide etchant may be different from each other. For example, etch selectivities of an oxide layer (e.g., a silicon oxide layer) and a nitride layer (e.g., a silicon nitride layer) for the buffered oxide etchant may be different from each other. In addition, etch selectivities of the insulating layers and the second active layer ACT2 for the buffered oxide etchant may be different from each other. Accordingly, when the buffered oxide etching is performed in a state where side surfaces of the lower insulating layer LIL, the second active layer ACT2, and the upper insulating layer UIL are exposed by the first contact hole CH1, a step structure may be formed at a sidewall of the first contact hole CH1.

For example, in an embodiment in which the buffered oxide etching is performed using a buffered oxide etchant including hydrofluoric acid (HF), a sidewall of an oxide layer (e.g., a silicon oxide layer) exposed by the first contact hole CH1 may be etched at a faster rate. Accordingly, the oxide layer may be opened wider (or recessed more) than a nitride layer in the first contact hole CH1. During the buffered oxide etching, the nitride layer (e.g., a silicon nitride layer) exposed by the first contact hole CH1 may be etched at a slower rate than the oxide layer. Accordingly, the nitride layer may be opened narrower (or recessed less) than the oxide layer in the first contact hole CH1. For example, in at least a portion of the first contact hole CH1 including the first sidewall portion, a silicon oxide layer included in the lower insulating layer LIL and the upper insulating layer UIL may be opened wider (e.g., recessed more) than a silicon nitride layer included in the lower insulating layer LIL and the upper insulating layer UIL. Accordingly, at least at the first sidewall portion, the first contact hole CH1 may include a step portion formed between a plurality of insulating layers included in the lower insulating layer LIL and the upper insulating layer UIL and including different materials from each other.

The first contact hole CH1 may not include a step portion formed between the insulating layers at the second sidewall portion facing the first sidewall portion (or at least one of the remaining sidewall portions of the first contact hole CH1 excluding the first sidewall portion, where the second active layer ACT2 is not located or exposed) or may include a step portion having a shorter length than the step portion formed between the insulating layers at the first sidewall portion. For example, a distance between ends of a pair of a silicon nitride layer and a silicon oxide layer exposed at the second sidewall portion, which are continuously stacked in the third direction DR3 among a plurality of insulating layers included in the lower insulating layer LIL and the upper insulating layer UIL, may be less than a distance between ends of the pair of the silicon nitride layer and the silicon oxide layer exposed at the first sidewall portion.

For example, as illustrated in FIG. 5, in an embodiment at the first sidewall portion of the first contact hole CH1, silicon nitride layers included in the lower insulating layer LIL and the upper insulating layer UIL may protrude more than silicon oxide layers towards a central portion of the first contact hole CH1 by a first protrusion length L_I1, and at the second sidewall portion of the first contact hole CH1, a step portion may not be substantially formed between the silicon nitride layers and the silicon oxide layers included in the lower insulating layer LIL and the upper insulating layer UIL. Alternatively, as illustrated in FIG. 6, in an embodiment at the first sidewall portion of the first contact hole CH1, the silicon nitride layers included in the lower insulating layer LIL and the upper insulating layer UIL may protrude more than the silicon oxide layers towards the central portion of the first contact hole CH1 by a second protrusion length L_I2, and at the second sidewall portion of the first contact hole CH1, the silicon nitride layers included in the lower insulating layer LIL and the upper insulating layer UIL may protrude more than the silicon oxide layers towards the central portion of the first contact hole CH1 by a third length L3 less than the second protrusion length L_I2.

During the buffered oxide etching, the second active layer ACT2 may not be substantially etched or may be etched at a slower rate than the lower insulating layer LIL and the upper insulating layer UIL. Accordingly, at the first sidewall portion of the first contact hole CH1, the second active layer ACT2 may protrude more than the lower insulating layer LIL and the upper insulating layer UIL towards the center of the first contact hole CH1. As a result, an undercut may be formed under the second active layer ACT2.

In an embodiment, the undercut under the second active layer ACT2 may have a length that can cause the first conductive pattern CP1 to be broken. Accordingly, the first conductive pattern CP1 may be broken under the second active layer ACT2. For example, in an embodiment the length (e.g., a first length L1 of FIG. 5 or a second length L2 of FIG. 6) of the undercut formed under the second active layer ACT2 may be greater than or equal to about 30 nm, and the first conductive pattern CP1 may be broken by the undercut.

The first length L1 or the second length L2 of the undercut that can cause the first conductive pattern CP1 to be broken may vary according to process conditions (e.g., process conditions for forming the first conductive pattern CP1). For example, if an undercut having a length in a range of about 10 to about 100 nm can cause the first conductive pattern CP1 to be broken, the first length L1 or the second length L2 of the undercut formed under the second active layer ACT2 may be in a range of about 10 to about 100 nm. Accordingly, the first conductive pattern CP1 may be broken under the second active layer ACT2.

On the other hand, if the first length L1 or the second length L2 of the undercut formed under the second active layer ACT2 is less than about 10 nm, the first conductive pattern CP1 may not be properly broken under the second active layer ACT2. If the first length L1 or the second length L2 of the undercut formed under the second active layer ACT2 is greater than or equal to about 100 nm, an etching amount of the lower insulating layer LIL and the upper insulating layer UIL may increase excessively, causing the first conductive pattern CP1 to be broken even in an unintended portion. This may result in a contact failure.

In an embodiment, the first sidewall portion and the second sidewall portion of the first contact hole CH1 may be asymmetrical. Accordingly, the first contact hole CH1 may include asymmetrical sidewalls.

For example, the first contact hole CH1 may include a step structure including an undercut under the second active layer ACT2 at the first sidewall portion where the second active layer ACT2 is exposed and may have a smoother shape at the second sidewall portion. For example, as illustrated in FIG. 5, the second sidewall portion of the first contact hole CH1 may have a substantially smooth shape without including a step structure such as an undercut. For example, the substantially smooth shape may mean a shape in which the sidewall portion extends in a substantially continuous curve or line. Alternatively, as illustrated in FIG. 6, the second sidewall portion of the first contact hole CH1 may have a relatively smooth shape with a gentle step structure compared to the first sidewall portion of the first contact hole CH1. For example, the second sidewall portion of the first contact hole CH1 may include a step structure having an undercut (e.g., a second undercut) of a length (e.g., the third length L3) less than a maximum length (e.g., the second length L2) of the undercut formed at the first sidewall portion and may have a relatively smooth shape. For example, the relatively smooth shape may mean that the undercut is relatively small and the sidewall portion extends largely in a continuous curve or line.

In an embodiment, during a period in which the buffered oxide etching is performed, the second sidewall portion of the first contact hole CH1 may be covered with a mask. Accordingly, the lower insulating layer LIL and the upper insulating layer UIL at the second sidewall portion of the first contact hole CH1 may be protected by the mask and may not be substantially etched. On the other hand, the first sidewall portion of the first contact hole CH1 may be exposed to the buffered oxide etchant without being covered with the mask. Accordingly, as illustrated in FIG. 5, the lower insulating layer LIL and the upper insulating layer UIL may be etched only at the first sidewall portion of the first contact hole CH1 to form the first contact hole CH1 including the asymmetrical sidewalls.

In an embodiment, the second sidewall portion of the first contact hole CH1 may be covered with the mask during a part of the period in which the buffered oxide etching is performed and may be exposed to the buffered oxide etchant during the remaining period. For example, in an embodiment even after the mask covering the second sidewall portion of the first contact hole CH1 is consumed, the buffered oxide etching may still be performed for a certain period of time to form the first contact hole CH1 according to the embodiment of FIG. 6. Accordingly, the lower insulating layer LIL and the upper insulating layer UIL may also be etched at the second sidewall portion of the first contact hole CH1.

An etching amount of the lower insulating layer LIL and the upper insulating layer UIL at the second sidewall portion of the first contact hole CH1 may be less than an etching amount of the lower insulating layer LIL and the upper insulating layer UIL at the first sidewall portion of the first contact hole CH1 which have been exposed to the buffered oxide etchant for a longer period of time. Accordingly, the lower insulating layer LIL and the upper insulating layer UIL may have a relatively large step at the first sidewall portion of the first contact hole CH1 and a relatively small step at the second sidewall portion of the first contact hole CH1.

At the first sidewall portion of the first contact hole CH1, the lower insulating layer LIL and the upper insulating layer UIL may be over-etched for a longer period of time. Accordingly, the length of the undercut formed under the second active layer ACT2 may increase. For example, the second length L2 of the undercut formed under the second active layer ACT2 in the embodiment of FIG. 6 may be greater than the first length L1 of the undercut formed under the second active layer ACT2 in the embodiment of FIG. 5. The first length L1 or the second length L2 of the undercut formed under the second active layer ACT2 may vary according to the materials, structures, and/or etching conditions of the lower insulating layer LIL and the upper insulating layer UIL.

In an embodiment, the process conditions under which the buffered oxide etching is performed may be controlled to form the asymmetrical first contact hole CH1 such that the maximum length (e.g., the third length L3) of the undercut formed at the second sidewall portion of the first contact hole CH1 is less than or equal to about 50% of the maximum length (e.g., the first length L1 or the second length L2) of the undercut formed at the first sidewall portion of the first contact hole CH1. By limiting the maximum length of the undercut formed at the second sidewall portion of the first contact hole CH1, it is possible to prevent the first conductive pattern CP1 from being broken at the second sidewall portion of the first contact hole CH1.

In an embodiment, the first conductive pattern CP1 may have a shape corresponding to the shape of the first contact hole CH1. For example, the first conductive pattern CP1 may have a step structure corresponding to the shape of the first sidewall portion at the first sidewall portion of the first contact hole CH1 and may be broken under the second active layer ACT2. For example, in an embodiment the first conductive pattern CP1 may cover upper and side surfaces (e.g., a lateral end) of the second active layer ACT2 exposed at the first sidewall portion of the first contact hole CH1, but may not directly contact a lower surface of the second active layer ACT2 exposed by the undercut under the second active layer ACT2.

The first conductive pattern CP1 may be a single layer or a multilayer. For example, in an embodiment the first conductive pattern CP1 may be a single layer including a main conductive layer CP1A or may be a multilayer including the main conductive layer CP1A and at least one barrier layer CP1B. For example, in an embodiment the first conductive pattern CP1 may be a single layer including molybdenum (Mo) or other metals or may be a multilayer of Ti/Cu, Ti/Al/Ti, Al/Ti, or Mo/Al/Mo.

The main conductive layer CP1A may be formed using a material (e.g., a metal) and/or to a thickness suitable for securing the conductivity of the first conductive pattern CP1. The main conductive layer CP1A may also be referred to as a “first metal layer.”

In an embodiment, the main conductive layer CP1A may include a low-resistance material (e.g., aluminum (Al), copper (Cu), or other low-resistance metals), and the first conductive pattern CP1 may further include at least one barrier layer CP1B disposed on and/or under the main conductive layer CP1A. For example, the first conductive pattern CP1 may further include a barrier layer CP1B (also referred to as a “second metal layer” or a “lower barrier layer”) located under the main conductive layer CP1A. The barrier layer CP1B may cover a lower surface of the main conductive layer CP1A.

The barrier layer CP1B may include a material suitable for preventing the diffusion of the low-resistance material included in the main conductive layer CP1A and may have conductivity. For example, in an embodiment the barrier layer CP1B may include titanium (Ti), titanium nitride (TiN), molybdenum (Mo), tungsten (W) or other barrier materials and may be formed as a thin layer having a smaller thickness (e.g., length in the third direction DR3) than the main conductive layer CP1A.

In an embodiment, the barrier layer CP1B may directly contact an end (e.g., a lateral end) of the second active layer ACT2 exposed by the first contact hole CH1 (e.g., the upper and side surfaces of the second active layer ACT2 exposed at the first sidewall portion of the first contact hole CH1). The main conductive layer CP1A may not directly contact the second active layer ACT2 and may be electrically connected to the second active layer ACT2 through the barrier layer CP1B. Accordingly, the diffusion of the material of the main conductive layer CP1A into the second active layer ACT2 can be prevented.

According to an embodiment, the first contact hole CH1 may have a differentiated or optimized sidewall structure for each of a connection path between the first conductive pattern CP1 and the first gate electrode GE1 and a connection path between the first conductive pattern CP1 and the second active layer ACT2. For example, the first contact hole CH1 may include an undercut under the second active layer ACT2 at the first sidewall portion where the second active layer ACT2 is exposed, and the first conductive pattern CP1 may be broken under the second active layer ACT2. The first conductive pattern CP1 may be continuous at another portion of the first contact hole CH1, for example, at the second sidewall portion. For example, the first contact hole CH1 may have a relatively smooth shape at the second sidewall portion facing the first sidewall portion compared to the first sidewall portion, and the first conductive pattern CP1 may be stably connected to the first gate electrode GE1 via the second sidewall portion. Accordingly, the diffusion of the material of the first conductive pattern CP1 into the second active layer ACT2 can be prevented or reduced, and a contact failure that may occur in the first contact hole CH1 can be prevented. As a result, the reliability of the display device 10 may be increased. In an embodiment, at the second sidewall portion, a semiconductor pattern such as the second active layer ACT2 may not be located or exposed.

In an embodiment, at the first sidewall portion (e.g., at the right sidewall portion) of the first contact hole CH1 where the second active layer ACT2 is exposed, the first conductive pattern CP1 may be formed continuously from the top of or above the first contact hole CH1 onto the exposed side surface of the second active layer ACT2. Accordingly, the first conductive pattern CP1 may be stably connected to the second active layer ACT2.

In addition, since the second active layer ACT2 protrudes towards the central portion of the first contact hole CH1 at the first sidewall portion of the first contact hole CH1, a contact area between the second active layer ACT2 and the first conductive pattern CP1 may increase. Accordingly, a current crowding phenomenon can be reduced or prevented, and contact resistance can be increased.

Additionally, at the first sidewall portion of the first contact hole CH1, the barrier layer CP1B of the first conductive pattern CP1 may cover the exposed upper and side surfaces of the second active layer ACT2, and the main conductive layer CP1A may be electrically connected to the second active layer ACT2 through the barrier layer CP1B. An undercut may be formed under the second active layer ACT2, and the first conductive pattern CP1 may be broken by the undercut. For example, the main conductive layer CP1A and the barrier layer CP1B of the first conductive pattern CP1 may be broken under the second active layer ACT2. Accordingly, the diffusion of the material of the main conductive layer CP1A into the second active layer ACT2 can be prevented. This can increase the reliability of the second active layer ACT2 and a circuit element (e.g., the second transistor T2) including the second active layer ACT2.

On the other hand, at the second sidewall portion (e.g., at the left sidewall portion) of the first contact hole CH1 facing the second active layer ACT2, the upper insulating layer UIL and the lower insulating layer LIL may not be etched, or an etching amount of the upper insulating layer UIL and the lower insulating layer LIL at the second sidewall portion of the first contact hole CH1 may be less than an etching amount at the first sidewall portion of the first contact hole CH1. For example, at the second sidewall portion of the first contact hole CH1, a difference in etching amount between insulating layers including different materials among the insulating layers that form the upper insulating layer UIL and the lower insulating layer LIL may be substantially non-existent or may be less than a difference in etching amount at the first sidewall portion of the first contact hole CH1.

Accordingly, the second sidewall portion of the first contact hole CH1 may be relatively smooth by substantially not having a step or by including a relatively gentle step. For example, even if a step including an undercut is formed at the second sidewall portion of the first contact hole CH1, a length of the undercut may be small enough to prevent breaking of the first conductive pattern CP1. For example, in an embodiment the maximum length (e.g., the third length L3) of the undercut may be less than or equal to about 50% of the maximum length (e.g., the first length L1 or the second length L2) of the undercut formed at the first sidewall portion of the first contact hole CH1 due to uneven etching of the insulating layers that form the upper insulating layer UIL and the lower insulating layer LIL at the second sidewall portion of the first contact hole CH1. For example, the third length L3 of the undercut formed at the second sidewall portion of the first contact hole CH1 may be less than or equal to about 30 nm, or less than or equal to about 10 nm.

Accordingly, the first conductive pattern CP1 can be stably formed inside the first contact hole CH1, and the breaking of the first conductive pattern CP1 can be prevented. For example, the first conductive pattern CP1 may extend continuously from the top of or above the first contact hole CH1 onto the bottom portion of the first contact hole CH1 via the second sidewall portion of the first contact hole CH1. For example, the upper pattern UPT, such as the first conductive pattern CP1 may extend continuously along the second sidewall portion. For example, the main conductive layer CP1A of the first conductive pattern CP1 may not be broken on the second sidewall portion of the first contact hole CH1 even if the second sidewall portion of the first contact hole CH1 has a slight step. The barrier layer CP1B of the first conductive pattern CP1 may or may not be broken depending on the shape of the second sidewall portion of the first contact hole CH1. The first conductive pattern CP1 may directly contact the first gate electrode GE1 at the bottom portion of the first contact hole CH1. Accordingly, the first conductive pattern CP1 can be stably connected to the first gate electrode GE1.

In an embodiment, a portion of the first conductive pattern CP1 disposed on the second active layer ACT2 and another portion of the first conductive pattern CP1 disposed on the second sidewall portion of the first contact hole CH1, which appear to be separated from each other in the cross-sectional views of FIGS. 5 and 6, may be connected to each other when seen in plan view. For example, when seen in plan view, the portion and the another portion of the first conductive pattern CP1 may be formed integrally by extending to around the first contact hole CH1.

In FIGS. 5 and 6, the first contact hole CH1 is shown as a contact hole that can have a structure according to embodiments of the present disclosure. However, the contact hole to which embodiments of the present disclosure can be applied is not limited to the first contact hole CH1 shown in FIG. 5 and. For example, the display device 10 may include a contact hole formed to penetrate a plurality of insulating to connect three or more patterns located in different layers from each other, and the contact hole may have a structure or shape according to at least one of the embodiments described above.

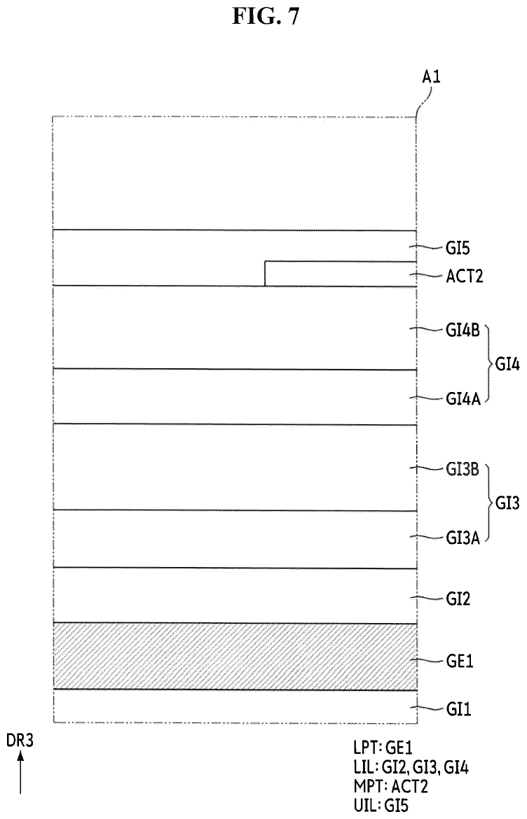

FIGS. 7 through 11 are cross-sectional views illustrating a method of manufacturing a display device according to embodiments of the present disclosure. For example, FIGS. 7 through 11 sequentially illustrate manufacturing operations for forming the first contact hole CH1 according to an embodiment of FIG. 5 and the first conductive pattern CP1 covering the first contact hole CH1 among manufacturing operations for manufacturing the display device 10 according to an embodiment of FIG. 4. FIGS. 7 through 11 show a part of the display device 10 being manufactured, which corresponds to area A1 of FIGS. 4 and 5.

Referring to FIG. 7 in addition to FIGS. 4 and 5, a lower pattern LPT (e.g., a first gate electrode GE1), a lower insulating layer LIL, a second active layer ACT2, and an upper insulating layer UIL (e.g., a fifth insulating layer GI5) may be sequentially formed on a substrate SUB (e.g., in the third direction DR3). For example, in an embodiment, after the first semiconductor layer SCL1 and the first insulating layer GI1 of FIG. 4 are formed on the substrate SUB, a first conductive layer GTL1 including the first gate electrode GE1, second, third and fourth insulating layers GI2, GI3 and GI4, a second semiconductor layer SCL2 including the second active layer ACT2, and the fifth insulating layer GI5 may be sequentially formed on the first insulating layer GI1 (e.g., in the third direction DR3). In an embodiment in which a second conductive layer GTL2 and a third conductive layer GTL3 are located between the second insulating layer GI2 and the fourth insulating layer GI4 as illustrated in FIG. 4, the second conductive layer GTL2, the third insulating layer GI3, the third conductive layer GTL3, the fourth insulating layer GI4, the second semiconductor layer SCL2, and the fifth insulating layer GI5 may be sequentially formed on the second insulating layer GI2 (e.g., in the third direction DR3) after the second insulating layer GI2 is formed on the first conductive layer GTL1.

In an embodiment, semiconductor patterns of each of the first semiconductor layer SCL1 and the second semiconductor layer SCL2 may be formed by a process (e.g., a deposition process) of forming a semiconductor layer using at least one semiconductor material (e.g., polysilicon) and a process of patterning the semiconductor layer (e.g., an etching process using a mask).

In an embodiment, each of the first insulating layer GI1, the second insulating layer GI2, the third insulating layer GI3, the fourth insulating layer GI4, and the fifth insulating layer GI5 may be formed by a process (e.g., a deposition process) of forming at least one insulating layer using at least one insulating material (e.g., silicon oxide, silicon nitride, silicon oxynitride, and/or other inorganic insulating materials).

Conductive patterns of each of the first conductive layer GTL1, the second conductive layer GTL2, and the third conductive layer GTL3 may be formed by a process (e.g., a deposition process) of forming a conductive layer using at least one conductive material (e.g., a conductive material exemplified above) and a process of patterning the conductive layer (e.g., an etching process using a mask).

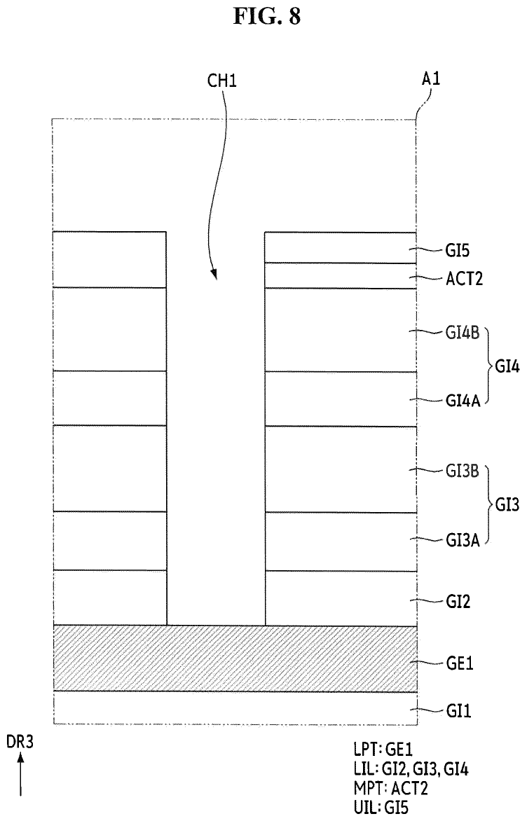

Referring to FIG. 8, the lower insulating layer LIL and the upper insulating layer UIL may be etched to form a first contact hole CH1 which exposes a portion of the lower pattern LPT and an end (e.g., a lateral end) of the second active layer ACT2. For example, in an embodiment the second, third, fourth and fifth insulating layers GI2, GI3, GI4 and GI5 may be etched in a vertical direction by a dry etching process using a mask pattern in an area where the first contact hole CH1 is to be formed.

Accordingly, the first contact hole CH1 which exposes a portion of the first gate electrode GE1 and an end of the second active layer ACT2 may be formed. For example, the first contact hole CH1 may include a bottom portion exposing a portion (e.g., a portion of an upper surface) of the first gate electrode GE1, a first sidewall portion (e.g., a right sidewall portion) exposing an end (e.g., a left end) of the second active layer ACT2, and a second sidewall portion (e.g., a left sidewall portion) facing the first sidewall portion.

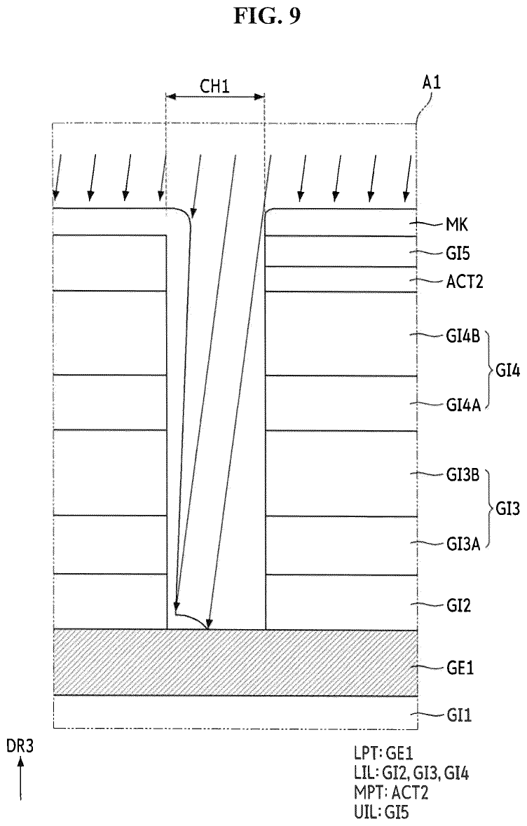

Referring to FIG. 9, a mask MK may be formed on the first contact hole CH1 to partially cover the sidewall portions of the first contact hole CH1. For example, in an embodiment the mask MK may be formed on the first contact hole CH1 to cover the second sidewall portion facing the end of the second active layer ACT2 (e.g., in a horizontal direction parallel to an upper surface of the substrate SUB) among the sidewall portions of the first contact hole CH1.

The mask MK may also be formed around the first contact hole CH1. For example, in an embodiment the mask MK may also be formed on the upper insulating layer UIL to surround the first contact hole CH1.

In an embodiment, the mask MK may be a self-aligned mask, for example, a self-aligned hard mask formed by an oblique sputtering method. In addition, the mask MK may include a material (e.g., an oxide) that can be removed in a post-treatment process including buffered oxide etching. For example, the mask MK may include an oxide semiconductor which includes a semiconductor material different from the material of the second active layer ACT2 and can be etched by a buffered oxide etchant. In this case, the mask MK can be removed in the post-treatment process without an additional process for removing the mask MK. Accordingly, the manufacturing efficiency of the display device 10 can be increased.

In an embodiment, the mask MK may include a material having a lower etching rate for the buffered oxide etchant than the lower insulating layer LIL and the upper insulating layer UIL. For example, in an embodiment the mask MK may include a material having a lower etching rate for the buffered oxide etchant than a silicon oxide layer and a silicon nitride layer. Accordingly, the mask MK may appropriately cover side surfaces of the lower insulating layer LIL and the upper insulating layer UIL located at the second sidewall portion of the first contact hole CH1 while the buffered oxide etching is performed in a subsequent process.

In an embodiment, the mask MK may include a material having a higher etching rate for the buffered oxide etchant than the first gate electrode GE1 and the second active layer ACT2. For example, the mask MK may include a material having a higher etching rate for the buffered oxide etchant than a conductive material included in the first gate electrode GE1 and a semiconductor material included in the second active layer ACT2. For example, in an embodiment the mask MK may include indium-gallium-zinc-oxide (IGZO) and may be gradually etched away by the buffered oxide etchant while the buffered oxide etching is performed in a subsequent process.

In an embodiment, a sputtering material may be deposited using the oblique sputtering method such that a portion of the first contact hole CH1 is exposed and that the mask MK is formed only on the other portion of the first contact hole CH1. For example, a sputtering angle may be adjusted or optimized so that a portion of the first contact hole CH1 including the first sidewall portion is exposed and that the mask MK is formed only on the other portion of the first contact hole CH1 including the second sidewall portion.

For example, in an embodiment, indium-gallium-zinc-oxide (IGZO) may be deposited at an angle of less than 90 degrees using an oblique sputter or a rotary sputter to form the mask MK which includes indium-gallium-zinc-oxide (IGZO) and covers an entirety of the second sidewall portion of the first contact hole CH1. For example, a self-aligned mask which partially covers the sidewall portions of the first contact hole CH1 may be formed by obliquely depositing a material of a sputtering target in a direction indicated by arrows in FIG. 9. An incident angle of particles from the sputtering target may be controlled according to the shape or size of the contact hole CH1 (e.g., the width and depth of the contact hole CH1). Accordingly, the mask MK can be appropriately placed at a desired position without a process for patterning the mask MK. In an embodiment, the mask MK may also be formed on a portion of the bottom portion of the first contact hole CH1 which is close to the second sidewall portion. However, embodiments of the present disclosure are not necessarily limited thereto.

The second active layer ACT2 may include a material having a lower etching rate for the buffered oxide etchant than the mask MK. For example, in an embodiment in which the mask MK includes indium-gallium-zinc-oxide (IGZO), the second active layer ACT2 may include polysilicon or crystallized indium-gallium-oxide (IGO).

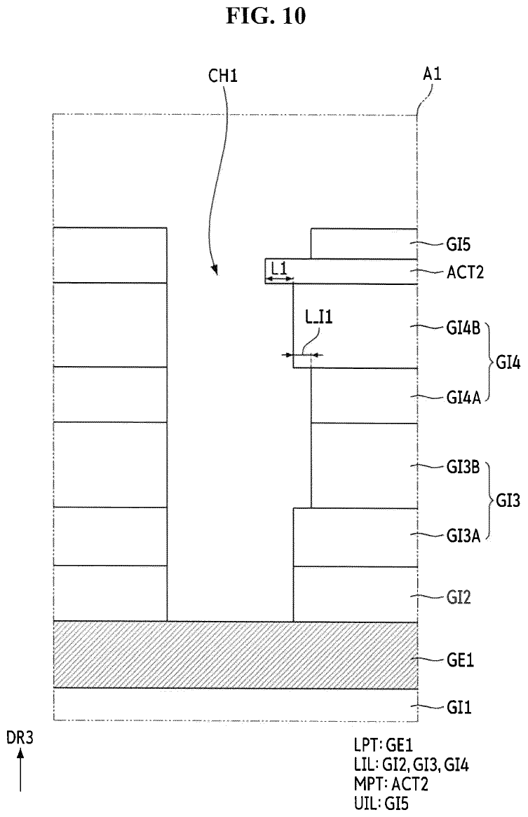

Referring to FIGS. 9 and 10, in an embodiment, in a state where a portion of the first contact hole CH1 including the first sidewall portion is exposed and where the other portion of the first contact hole CH1 including an entirety of the second sidewall portion is covered with the mask MK, the buffered oxide etching may be performed. For example, a side surface of each of the lower insulating layer LIL and the upper insulating layer UIL exposed at the first sidewall portion of the first contact hole CH1 may be etched using the buffered oxide etchant, and an undercut having a first length L1 may be formed under the second active layer ACT2. Accordingly, the asymmetrical first contact hole CH1 may be formed as shown in an embodiment of FIG. 5.

When the lower insulating layer LIL and the upper insulating layer UIL include a plurality of insulating layers (e.g., silicon nitride layers and silicon oxide layers) including materials having different etching rates for the buffered oxide etchant, the insulating layers of the different materials from each other in the lower insulating layer LIL and the upper insulating layer UIL may be etched at different rates during the buffered oxide etching. For example, in an embodiment, silicon nitride layers (e.g., the second insulating layer GI2, a first layer GI3A of the third insulating layer GI3 and a second layer GI4B of the fourth insulating layer GI4) and silicon oxide layers (e.g., a second layer GI3B of the third insulating layer GI3, a first layer GI4A of the fourth insulating layer GI4 and the fifth insulating layer GI5) included in the lower insulating layer LIL and the upper insulating layer UIL may be etched at different rates from each other. For example, the silicon oxide layers may be etched at a faster rate than the silicon nitride layers. Accordingly, a step portion, such as an undercut, may be formed at a boundary between the silicon oxide layers and the silicon nitride layers in at least a portion of the first contact hole CH1 including the first sidewall portion. For example, at the first sidewall portion of the first contact hole CH1, the silicon nitride layers may protrude more than the silicon oxide layers towards a central portion of the first contact hole CH1 by a first protrusion length L_I1.

In an embodiment, the second active layer ACT2 may include a material (e.g., polysilicon or crystallized indium-gallium-oxide (IGO)) having high corrosion resistance to the buffered oxide etchant and may not be etched during the buffered oxide etching. Accordingly, an undercut may be formed under the second active layer ACT2.

In an embodiment, the buffered oxide etching may be performed to form an undercut of a length, which can cause breaking of a first conductive pattern CP1, under the second active layer ACT2. For example, in an embodiment the buffered oxide etching may be performed until an undercut having a first length L1 in a range of about 10 to about 100 nm is formed under the second active layer ACT2 at the first sidewall portion of the first contact hole CH1.

In an embodiment, the mask MK may also be etched away by a material (e.g., hydrofluoric acid (HF)) of the buffered oxide etchant used in the buffered oxide etching. For example, the buffered oxide etching may be performed until the mask MK is etched to expose the lower insulating layer LIL and the upper insulating layer UIL at the second sidewall portion of the first contact hole CH1.

In an embodiment, process conditions under which the buffered oxide etching is performed may be controlled so that an undercut is not formed at the second sidewall portion of the first contact hole CH1 or that a maximum length of an undercut formed at the second sidewall portion of the first contact hole CH1 is less than or equal to about 50% of a maximum length (e.g., the first length L1) of the undercut formed at the first sidewall portion of the first contact hole CH1. Accordingly, the second sidewall portion of the first contact hole CH1 may be formed in a smoother shape than the first sidewall portion.

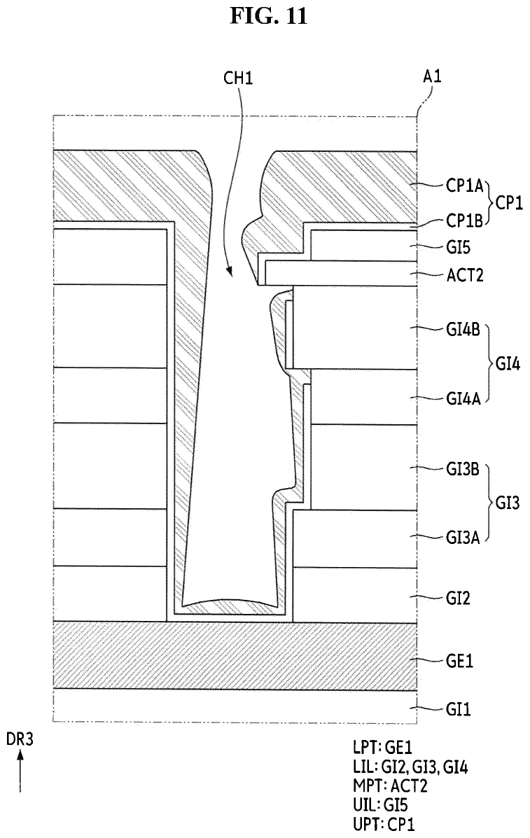

Referring to FIG. 11, an upper pattern UPT may be formed on the upper insulating layer UIL to cover the first contact hole CH1. For example, in an embodiment a fourth conductive layer GTL4 including the first conductive pattern CP1 may be formed on the fifth insulating layer GI5.

In an embodiment, conductive patterns of the fourth conductive layer GTL4 may be formed by a process (e.g., a deposition process) of forming a conductive layer using at least one conductive material (e.g., a conductive material described above) and a process of patterning the conductive layer (e.g., an etching process using a mask). In an embodiment, each of the conductive patterns of the fourth conductive layer GTL4 may be formed as a multilayer including a main conductive layer and a barrier layer. For example, in an embodiment the first conductive pattern CP1 may be formed as a multilayer including a main conductive layer CP1A and a barrier layer CP1B. In this embodiment, after a lower conductive layer for forming the barrier layer CP1B and an upper conductive layer for forming the main conductive layer CP1A are sequentially formed, the lower conductive layer and the upper conductive layer may be patterned simultaneously. The first conductive pattern CP1 may cover the first contact hole CH1 and may have a shape corresponding to the shape of the first contact hole CH1.

Through the process described above with reference to FIGS. 7 through 11, the first semiconductor layer SCL1, the first insulating layer GI1, the first conductive layer GTL1, the second insulating layer GI2, the second conductive layer GTL2, the third insulating layer GI3, the third conductive layer GTL3, the fourth insulating layer GI4, the second semiconductor layer SCL2, the fifth insulating layer GI5, and the fourth conductive layer GTL4 may be formed on the substrate SUB.

In an embodiment, a circuit layer CRL may then be formed by forming the sixth insulating layer GI6, the fifth conductive layer GTL5, the seventh insulating layer GI7, the sixth conductive layer SDL1, the eighth insulating layer ILD1, the seventh conductive layer SDL2, the ninth insulating layer ILD2, the eighth conductive layer SDL3, and the tenth insulating layer VIA of FIG. 4 on the fourth conductive layer GTL4. The circuit layer CRL may include a via hole VH exposing a portion of a sixth conductive pattern CP6 in each pixel area.

In an embodiment, the light emitting element layer EDL and the encapsulation layer TFEL of FIG. 4 may be sequentially formed on the circuit layer CRL (e.g., in the third direction DR3). Accordingly, the display device 10 according to an embodiment of FIG. 4 may be manufactured.

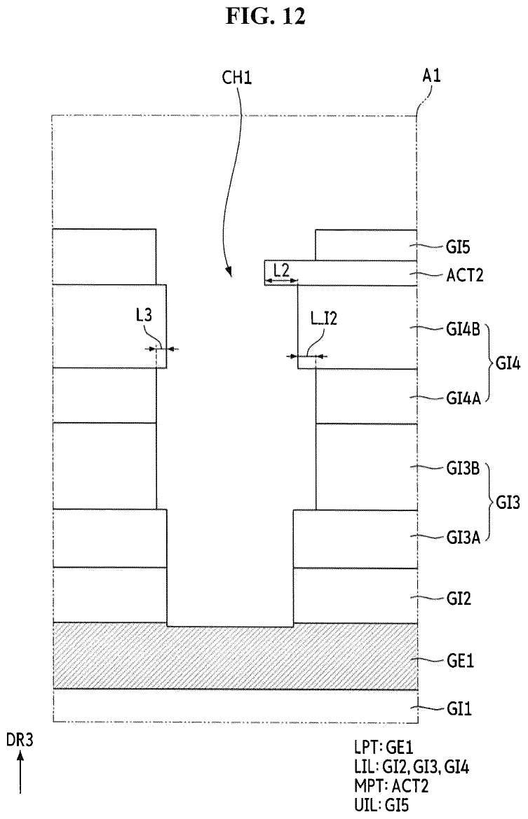

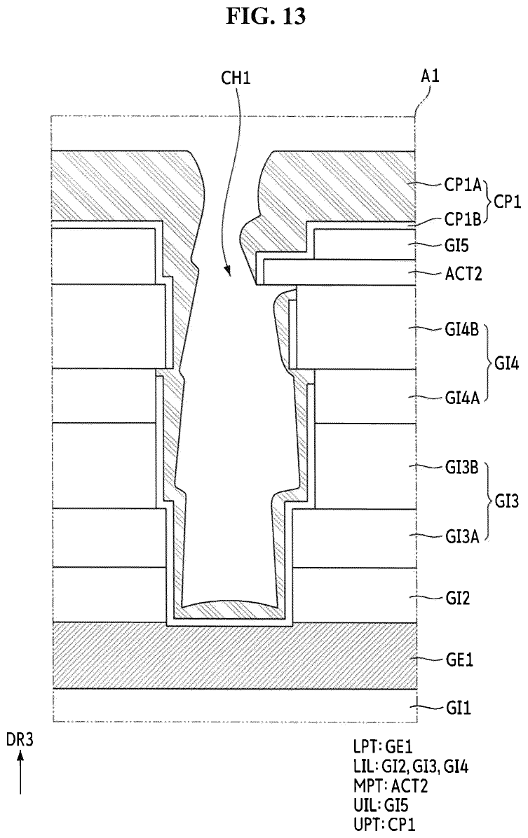

FIGS. 12 and 13 are cross-sectional views illustrating a method of manufacturing a display device according to an embodiment. For example, FIGS. 12 and 13 sequentially illustrate manufacturing operations for forming the first contact hole CH1 according to an embodiment of FIG. 6 and the first conductive pattern CP1 covering the first contact hole CH1 among manufacturing operations for manufacturing the display device 10 according to an embodiment of FIG. 4. FIGS. 12 and 13 show a portion of the display device 10 being manufactured, which corresponds to area A1 of FIGS. 4 and 6.

In the manufacturing of the display device 10 according to an embodiment of FIGS. 4 and 6, processes before a mask MK used in buffered oxide etching is removed may be substantially the same as or similar to the processes described with reference to FIGS. 7 through 10. For example, after a lower pattern LPT, a lower insulating layer LIL, a second active layer ACT2, and an upper insulating layer UIL are sequentially formed on a substrate SUB as illustrated in FIG. 7, the lower insulating layer LIL and the upper insulating layer UIL may be etched to form a first contact hole CH1 as illustrated in FIG. 8. In an embodiment, the mask MK may then be formed on the first contact hole CH1 to cover an entirety of the second sidewall portion of the first contact hole CH1 as illustrated in FIG. 9, and the lower insulating layer LIL and the upper insulating layer UIL exposed at a first sidewall portion of the first contact hole CH1 may be additionally etched by the buffered oxide etching to form an asymmetrical first contact hole CH1 as illustrated in FIG. 10.

Referring to FIG. 12 in addition to FIGS. 9 and 10, even after the mask MK is etched away by a buffered oxide etchant, the buffered oxide etching may still be performed for a certain period of time or longer. For example, even after the mask MK is completely consumed and removed by the buffered oxide etching, over-etching may be performed for a certain period of time or longer. For example, in an embodiment the buffered oxide etching may be performed until the lower insulating layer LIL and the upper insulating layer UIL exposed at the second sidewall portion of the first contact hole CH1 due to the removal of the mask MK are etched. Accordingly, a slight (e.g., relatively small) step may also be formed at the second sidewall portion of the first contact hole CH1. For example, at the first sidewall portion of the first contact hole CH1, silicon nitride layers included in the lower insulating layer LIL and the upper insulating layer UIL may protrude more than silicon oxide layers towards a central portion of the first contact hole CH1 by a second protrusion length L_I2, and at the second sidewall portion of the first contact hole CH1, the silicon nitride layers included in the lower insulating layer LIL and the upper insulating layer UIL may protrude more than the silicon oxide layers towards the central portion of the first contact hole CH1 by a third length L3 less than the second protrusion length L_I2. According to the above-described embodiment, the mask MK can be removed more stably by performing the buffered oxide etching for a sufficient time. For example, in the buffered oxide etching, over-etching may be performed in consideration of an error range due to process dispersion, so that the mask MK does not remain.

In an embodiment, the duration of the over-etching may be limited so that a maximum length of an undercut caused by a step formed at the second sidewall portion of the first contact hole CH1, for example, the third length L3 becomes less than or equal to a reference value. The reference value may be set to a value at which breaking of a first conductive pattern CP1 can be prevented and may vary according to the size or formation conditions of the first conductive pattern CP1. For example, in an embodiment the duration of the buffered oxide etching may be limited so that the third length L3 becomes less than or equal to about 50% of a maximum length (e.g., a second length L2) of an undercut formed at the first sidewall portion of the first contact hole CH1 or that the third length L3 becomes less than or equal to about 30 nm, or less than or equal to about 10 nm. When the third length L3 is less than or equal to about 30 nm, the risk of the first conductive pattern CP1 being broken at the second sidewall portion of the first contact hole CH1 can be reduced. When the third length L3 is less than or equal to about 10 nm, the first conductive pattern CP1 can be more effectively prevented from being broken at the second sidewall portion of the first contact hole CH1.

A portion of a first gate electrode GE1 exposed at a bottom portion of the first contact hole CH1 may not be etched or may be etched by a certain thickness during the buffered oxide etching. For example, the first gate electrode GE1 exposed at the bottom portion of the first contact hole CH1 may be etched by a fine thickness by over-etching, but embodiments of the present disclosure are not necessarily limited thereto.

Referring to FIG. 13, in an embodiment an upper pattern UPT may be formed on the upper insulating layer UIL to cover the first contact hole CH1. For example, a fourth conductive layer GTL4 including the first conductive pattern CP1 may be formed on a fifth insulating layer GI5. The method of forming the fourth conductive layer GTL4 may be substantially the same as or similar to the method of forming the fourth conductive layer GTL4 described with reference to FIG. 11. The first conductive pattern CP1 may cover the first contact hole CH1 and may have a shape corresponding to the shape of the first contact hole CH1.

In an embodiment, after the formation of the fourth conductive layer GTL4 including the first conductive pattern CP1, a circuit layer CRL may be formed by forming the sixth insulating layer GI6, the fifth conductive layer GTL5, the seventh insulating layer GI7, the sixth conductive layer SDL1, the eighth insulating layer ILD1, the seventh conductive layer SDL2, the ninth insulating layer ILD2, the eighth conductive layer SDL3, and the tenth insulating layer VIA of FIG. 4. The light emitting element layer EDL and the encapsulation layer TFEL of FIG. 4 may then be sequentially formed on the circuit layer CRL.

The display device 10 according to an embodiment of the present disclosure can be applied to various electronic devices. The electronic device according to an embodiment of the present disclosure includes the display device 10 described above, and may further include modules or devices having additional functions in addition to the display device 10.

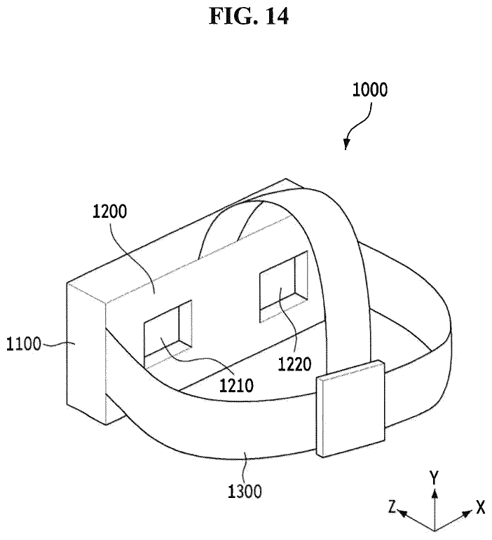

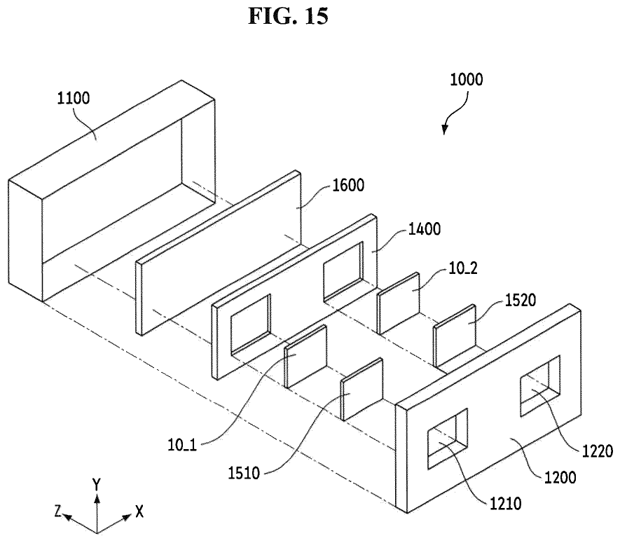

FIG. 14 is a perspective view of a head-mounted display device 1000 according to an embodiment. FIG. 15 is an exploded perspective view of an example of the head-mounted display device 1000 of FIG. 14.

Referring to FIGS. 14 and 15, the head-mounted display device 1000 according to an embodiment includes a first display device 10_1, a second display device 10_2, a display device housing 1100, a housing cover 1200, a first eyepiece 1210, a second eyepiece 1220, a head-mounted band 1300, a middle frame 1400, a first optical member 1510, a second optical member 1520, and a control circuit board 1600.

The first display device 10_1 provides an image to a user's left eye, and the second display device 10_2 provides an image to the user's right eye. In an embodiment, each of the first display device 10_1 and the second display device 10_2 may be the display device 10 described with reference to FIGS. 1 through 6. Therefore, a description of the first display device 10_1 and the second display device 10_2 will be omitted for economy of explanation.

The first optical member 1510 may be located between the first display device 10_1 and the first eyepiece 1210. The second optical member 1520 may be located between the second display device 10_2 and the second eyepiece 1220. Each of the first optical member 1510 and the second optical member 1520 may include at least one convex lens.

The middle frame 1400 may be located between the first display device 10_1 and the control circuit board 1600 and may be located between the second display device 10_2 and the control circuit board 1600. The middle frame 1400 supports and fixes the first display device 10_1, the second display device 10_2, and the control circuit board 1600.

The control circuit board 1600 may be located between the middle frame 1400 and the display device housing 1100. The control circuit board 1600 may be connected to the first display device 10_1 and the second display device 10_2 through a connector. The control circuit board 1600 may convert an image source received from the outside into digital video data DATA and transmit the digital video data DATA to the first display device 10_1 and the second display device 10_2 through the connector.

The control circuit board 1600 may transmit the digital video data DATA corresponding to a left image optimized for a user's left eye to the first display device 10_1 and transmit the digital video data DATA corresponding to a right image optimized for the user's right eye to the second display device 10_2. Alternatively, the control circuit board 1600 may transmit the same digital video data DATA to the first display device 10_1 and the second display device 10_2.

The display device housing 1100 houses the first display device 10_1, the second display device 10_2, the middle frame 1400, the first optical member 1510, the second optical member 1520, and the control circuit board 1600. The housing cover 1200 is placed to cover an open surface of the display device housing 1100. The housing cover 1200 may include the first eyepiece 1210 on which a user's left eye is placed and the second eyepiece 1220 on which the user's right eye is placed. Although the first eyepiece 1210 and the second eyepiece 1220 are located separately in FIGS. 14 and 15, embodiments of the present specification are not necessarily limited thereto. The first eyepiece 1210 and the second eyepiece 1220 may also be combined into one.

The first eyepiece 1210 may be aligned with the first display device 10_1 and the first optical member 1510, and the second eyepiece 1220 may be aligned with the second display device 10_2 and the second optical member 1520. Therefore, a user can view an image of the first display device 10_1, which is magnified as a virtual image by the first optical member 1510, through the first eyepiece 1210 and can view an image of the second display device 10_2, which is magnified as a virtual image by the second optical member 1520, through the second eyepiece 1220.

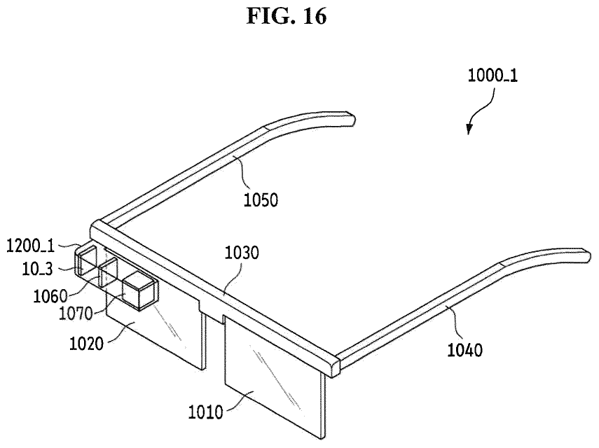

The head-mounted band 1300 fixes the display device housing 1100 to a user's head so that the first eyepiece 1210 and the second eyepiece 1220 of the housing cover 1200 are kept placed on the user's left and right eyes, respectively. When the housing cover 1200 is implemented to be lightweight and small, the head-mounted display device 1000 may include an eyeglass frame as illustrated in FIG. 16 instead of the head-mounted band 1300.

In addition, the head-mounted display device 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 16 is a perspective view of a head-mounted display device 1000_1 according to an embodiment.

Referring to FIG. 16, the head-mounted display device 1000_1 according to an embodiment may be a glasses-type display device in which a display device housing 1200_1 is implemented to be lightweight and small. The head-mounted display device 1000_1 according to an embodiment may include a display device 10_3, a left lens 1010, a right lens 1020, a support frame 1030, eyeglass frame legs 1040 and 1050, an optical member 1060, an optical path conversion member 1070, and the display device housing 1200_1.

The display device housing 1200_1 may include the display device 10_3, the optical member 1060, and the optical path conversion member 1070. In an embodiment, the display device 10_3 may be the display device 10 described with reference to FIGS. 1 through 6. An image displayed on the display device 10_3 may be magnified by the optical member 1060, may have its optical path converted by the optical path conversion member 1070, and then may be provided to a user's right eye through the right lens 1020. Accordingly, the user can view, through the right eye, an augmented reality image into which a virtual image displayed on the display device 10_3 and a real image viewed through the right lens 1020 are combined.

Although the display device housing 1200_1 is located at a right end of the support frame 1030 in FIG. 16, embodiments of the present specification are not necessarily limited thereto. For example, the display device housing 1200_1 may also be located at a left end of the support frame 1030. In this embodiment, an image of the display device 10_3 may be provided to a user's left eye. Alternatively, the display device housing 1200_1 may be located at both the left and right ends of the support frame 1030. In this embodiment, the user can view an image displayed on the display device 10_3 through both the left and right eyes.

FIGS. 14 through 16 disclose embodiments of a head-mounted display device (1000, 1000_1) as examples of an electronic device that may include a display device 10 according to embodiments described above (or a part of the display device 10 including a display panel). However, the electronic device that may include the display device 10 or the display panel according to an embodiment of the present disclosure is not limited to the head-mounted display devices 1000 and 1000_1 disclosed in FIGS. 14 through 16. For example, the display device 10 or the display panel according to an embodiment of the present disclosure may be included in electronic devices of other types or structures in addition to the head-mounted display devices 1000 and 1000_1.

In addition, the electronic device including the display device 10 according to an embodiment or the display panel according to an embodiment (e.g., a display panel including a circuit layer CRL according to an embodiment) may further include a housing (e.g., a housing such as the display device housing 1100 of FIGS. 14 and 15 or the display device housing 1200_1 of FIG. 16) for accommodating the display device 10 or the display panel.

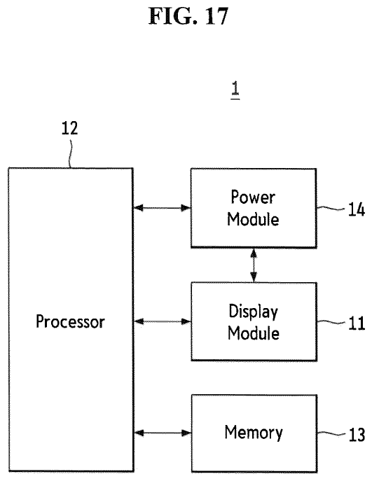

FIG. 17 is a block diagram of an electronic device according to an embodiment of the present disclosure.

Referring to FIG. 17, the electronic device 1 according to an embodiment of the present disclosure may include a display module 11, a processor 12, a memory 13, and a power module 14.

The display module 11 may include a display panel for displaying an image. For example, the display module 11 may include the display panel (e.g., a display panel of a display device 10) according to at least one embodiment described above.

The processor 12 may include at least one of a central processing unit (CPU), an application processor (AP), a graphic processing unit (GPU), a communication processor (CP), an image signal processor (ISP), and a controller.

The memory 15 may store data information necessary for the operation of the processor 12 or the display module 11. The processor 12 may transmit an image data signal and/or an input control signal stored in the memory 15 to the display module 11. For example, the processor 12 executes an application stored in the memory 15, the image data signal and/or the input control signal is transmitted to the display module 11, and the display module 11 can process the received signal and output image information through a display screen.

The power module 14 may include a power supply module such as, for example a power adapter or a battery, and a power conversion module that converts the power supplied by the power supply module to generate power necessary for the operation of the electronic device 10.

At least one of the components of the electronic device 1 according to an embodiment of the present disclosure may be included in the display device 10 according to an embodiment of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device 1 other than the display device 10.

In concluding the detailed description, those skilled in the art will appreciate that many variations and modifications can be made to the described embodiments without substantially departing from the principles of the present disclosure. Therefore, the described embodiments of the present disclosure are used in a generic and descriptive sense only and not for purposes of limitation.

What is claimed is:

1. A display device comprising:
a substrate;
a lower pattern disposed on the substrate;
a lower insulating layer disposed on the lower pattern;
an active layer disposed on the lower insulating layer and having at least a portion that includes an end of the active layer overlapping the lower pattern;
an upper insulating layer disposed on the active layer;
a contact hole penetrating the lower insulating layer and the upper insulating layer to expose a portion of the lower pattern and the end of the active layer; and
an upper pattern disposed on the upper insulating layer and the contact hole and electrically connected to the lower pattern and the active layer through the contact hole,
wherein the contact hole comprises a bottom portion exposing the portion of the lower pattern, a first sidewall portion exposing the end of the active layer and comprising an undercut positioned under the active layer and a second sidewall portion facing the first sidewall portion, and
the upper pattern directly contacts the end of the active layer at the first sidewall portion, the upper pattern is broken under the active layer and the upper pattern is continuous along the second sidewall portion.

2. The display device of claim 1, wherein:
the lower insulating layer and the upper insulating layer comprise a plurality of insulating layers covered with the upper pattern at the first sidewall portion and the second sidewall portion and comprising different materials from each other;
the first sidewall portion comprises a step portion formed between the plurality of insulating layers; and
the second sidewall portion does not comprise a step portion formed between the plurality of insulating layers or comprises a step portion having a shorter length than the step portion formed between the plurality of insulating layers at the first sidewall portion.

3. The display device of claim 1, wherein:
the first sidewall portion comprises a step structure comprising the undercut; and
the second sidewall portion has a substantially smooth shape.

4. The display device of claim 1, wherein:
the first sidewall portion comprises a step structure comprising the undercut; and
the second sidewall portion comprises a step structure comprising a second undercut having a shorter length than the undercut of the first sidewall portion.

5. The display device of claim 4, wherein a maximum length of the undercut formed at the second sidewall portion is less than or equal to about 50% of a maximum length of the undercut of the first sidewall portion.

6. The display device of claim 1, wherein:
the active layer is disposed only at the first sidewall portion among the first sidewall portion and the second sidewall portion; and
the first sidewall portion and the second sidewall portion have a same stacked structure except for an inclusion of the active layer in the first sidewall portion.

7. The display device of claim 1, wherein the upper pattern extends continuously from a top of the contact hole onto the bottom portion of the contact hole via the second sidewall portion of the contact hole.

8. The display device of claim 1, wherein the lower insulating layer and the upper insulating layer comprise a silicon oxide layer and a silicon nitride layer.

9. The display device of claim 8, wherein the silicon oxide layer is opened wider than the silicon nitride layer in at least a portion of the contact hole comprising the first sidewall portion.

10. The display device of claim 1, wherein the active layer protrudes more than the lower insulating layer and the upper insulating layer towards a center of the contact hole at the first sidewall portion.

11. The display device of claim 1, wherein:
the active layer comprises a lower surface exposed by the undercut at the first sidewall portion; and
the upper pattern does not contact the lower surface of the active layer.

12. The display device of claim 1, wherein a length of the undercut is in a range of about 10 nm to about 100 nm.

13. The display device of claim 1, wherein the upper pattern comprises a main conductive layer and a barrier layer under the main conductive layer.

14. The display device of claim 13, wherein the barrier layer directly contacts the end of the active layer, and the main conductive layer does not contact the active layer and is electrically connected to the active layer through the barrier layer.

15. A method of manufacturing a display device, the method comprising:
sequentially forming a lower pattern, a lower insulating layer, an active layer, and an upper insulating layer on a substrate;
forming a contact hole exposing a portion of the lower pattern and an end of the active layer by etching the lower insulating layer and the upper insulating layer;
forming a mask on an entirety of a second sidewall portion facing a first sidewall portion where the active layer is exposed among sidewall portions of the contact hole;
forming an undercut under the active layer by performing buffered oxide etching in a state where the first sidewall portion is exposed by the mask; and
forming an upper pattern that is electrically connected to the lower pattern and the active layer through the contact hole on the upper insulating layer and the contact hole.

16. The method of claim 15, wherein the forming of the mask comprises depositing a sputtering material only on a portion of the contact hole comprising the entirety of the second sidewall portion by using an oblique sputtering method.

17. The method of claim 15, wherein:
the performing of the buffered oxide etching comprises etching a side surface of each of the lower insulating layer and the upper insulating layer exposed by the mask at the first sidewall portion by using a buffered oxide etchant; and
the mask comprises a material having a lower etching rate for the buffered oxide etchant than the lower insulating layer and the upper insulating layer.

18. The method of claim 17, wherein:
the active layer comprises a material having a lower etching rate for the buffered oxide etchant than the mask; and
the lower insulating layer and the upper insulating layer comprise a plurality of insulating layers including materials having different etching rates for the buffered oxide etchant from each other, the plurality of insulating layers form a step portion at least at the first sidewall portion.

19. The method of claim 15, wherein:
the buffered oxide etching is performed until the mask is etched to expose the lower insulating layer and the upper insulating layer at the second sidewall portion; or
the buffered oxide etching is performed until the mask is etched and the lower insulating layer and the upper insulating layer exposed at the second sidewall portion is etched.

20. An electronic device comprising:
a display panel comprising a substrate and a circuit layer on the substrate; and
a housing for accommodating the display panel,
wherein the circuit layer comprises:
a lower pattern disposed on the substrate;
a lower insulating layer disposed on the lower pattern;
an active layer disposed on the lower insulating layer and having at least a portion that includes an end of the active layer overlapping the lower pattern;
an upper insulating layer disposed on the active layer;
a contact hole penetrating the lower insulating layer and the upper insulating layer to expose a portion of the lower pattern and the end of the active layer; and
an upper pattern disposed on the upper insulating layer and the contact hole and electrically connected to the lower pattern and the active layer through the contact hole,
wherein the contact hole comprises a bottom portion exposing the portion of the lower pattern, a first sidewall portion exposing the end of the active layer and comprising an undercut positioned under the active layer and a second sidewall portion facing the first sidewall portion, and
the upper pattern directly contacts the end of the active layer at the first sidewall portion, the upper pattern is broken under the active layer and the upper pattern is continuous along the second sidewall portion.
